(19) United States
(12) Patent Application Publication
(10) Pub. No.: US 2026/0143776 A1
(43) Pub. Date: May 21, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Tung-Yang LIN, New Taipei City (TW); Ruey-Hsin LIU, Hsin-Chu (TW)

(21) Appl. No.: 18/955,062

(22) Filed: Nov. 21, 2024

(51) Int. Cl. H01L 29/417; H01L 21/763; H01L 27/06

(52) U.S. Cl. CPC H10D 64/258; H10D 64/254; H10D 84/40; H10W 10/041; H10W 10/40

(57) ABSTRACT

A deep trench structure may be formed to include a doped polysilicon core and dielectric isolation layers on the sidewalls of the doped polysilicon core. The deep trench structure may be provided as a deep trench isolation structure that laterally surrounds transistors in a semiconductor device. Additionally and/or alternatively, the deep trench structure may be included in a high-voltage transistor as a vertical drain region that extends into a semiconductor layer of a semiconductor device.

### BACKGROUND

A high-voltage transistor is a type of metal oxide semiconductor (MOS) transistor that may be configured to operate at a higher drain voltage relative to a low voltage transistor. Low voltage transistors may be used in applications such as logic circuits (e.g., processors), memory (e.g., static random access memory (SRAM)), and/or input/output (I/O) circuits, among other examples. High-voltage transistors may be used in applications such as integrated circuit (IC) drivers, power ICs, image sensors, power management, display driver ICs (DDICs), bipolar complementary metal oxide semiconductor (CMOS) diffused metal oxide semiconductor (DMOS) ICs (BCD ICs), and/or image signal processing (ISP) ICs, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A and 2B are diagrams of an example implementation of an integrated circuit device described herein.

FIGS. 3A-3K are diagrams of an example implementation of forming an integrated circuit device that includes a vertical source/drain region described herein.

FIG. 4 is a diagram of an example implementation of an integrated circuit device described herein.

FIGS. 5A-5G are diagrams of an example implementation of forming an integrated circuit device that includes a vertical source/drain region described herein.

FIG. 6 is a diagram of an example implementation of an integrated circuit device described herein.

FIGS. 7A and 7B are diagrams of an example implementation of an isolated device region of a semiconductor device described herein.

FIGS. 8A-8F are diagrams of an example implementation of forming an isolated device region in a semiconductor device described herein.

FIG. 9 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To operate at higher drain voltages, a high-voltage transistor may be manufactured to withstand a high breakdown voltage. Breakdown voltage is a voltage at or near which a transistor ceases to operate according to the intended operating principles of the transistor. In a high-voltage transistor, gate-to-drain voltages may sometimes satisfy or exceed the breakdown voltage of the high-voltage transistor, due to the high drain voltages experienced by the high-voltage transistor.

In some cases, a high-voltage transistor may be manufactured such that a minimum distance between a gate structure and a drain region of the high-voltage transistor enables a particular breakdown voltage (BV) to be achieved by the high-voltage transistor. Increasing the distance between the gate structure and the drain region provides a drift region in which distribution of an electric field is provided between the gate structure and the drain region, which reduces the peak magnitude of the electric field (thereby increasing the breakdown voltage).

However, increasing the distance between the gate structure and the drain region increases the lateral footprint for the high-voltage transistor, which results in reducing the density of high-voltage transistors that can be integrated onto a semiconductor device without increasing the lateral footprint of the semiconductor device.

In some implementations described herein, a high-voltage transistor includes a vertical drain region that extends into a semiconductor layer of a semiconductor device. The vertical drain region may be electrically isolated from the semiconductor layer by dielectric isolation layers that extend along the sidewalls of the vertical drain region. The electrical isolation provided by the dielectric isolation layers enables the diffusion region of the high-voltage transistor to extend vertically in the semiconductor layer, as opposed to horizontally, which enables the vertical drain region to be positioned closer to the gate structure of the high-voltage transistor. In this way, a reduced lateral footprint may be achieved for the high-voltage transistor while still enabling a high breakdown voltage and a low on resistance (Rₒₙ) to be achieved for the high-voltage transistor.

Additionally and/or alternatively, a deep trench isolation (DTI) structure may be provided laterally around the high-voltage transistor (and/or around other transistors in the semiconductor device), and the DTI structure may include a similar arrangement as the vertical drain region, in that the DTI structure may include a doped polysilicon layer with dielectric isolation layers on the sidewalls of the doped polysilicon layer. The use of the DTI structure for electrical isolation enables less complex manufacturing processes to be used to connect the DTI structure to an underlying doped buried layer than if other electrical isolation techniques were used (such as those formed by multi-step epitaxy). Moreover, this enables the doped buried layer to be positioned deeper in the semiconductor layer, which provides for a greater area in the semiconductor layer for transistors. In addition, the DTI structure may be more resistant to electrical effects such as parasitic capacitance, parasitic P-N junction formation, parasitic bipolar junction transistor (BJT) formation, and/or current leakage, among other examples. Further, the DTI structure may be formed to have a high aspect ratio (e.g., a ratio of a depth to a width), which enables the DTI structure to occupy a smaller lateral footprint than other types of electrical isolation. This provides for a greater area in the semiconductor layer for transistors.

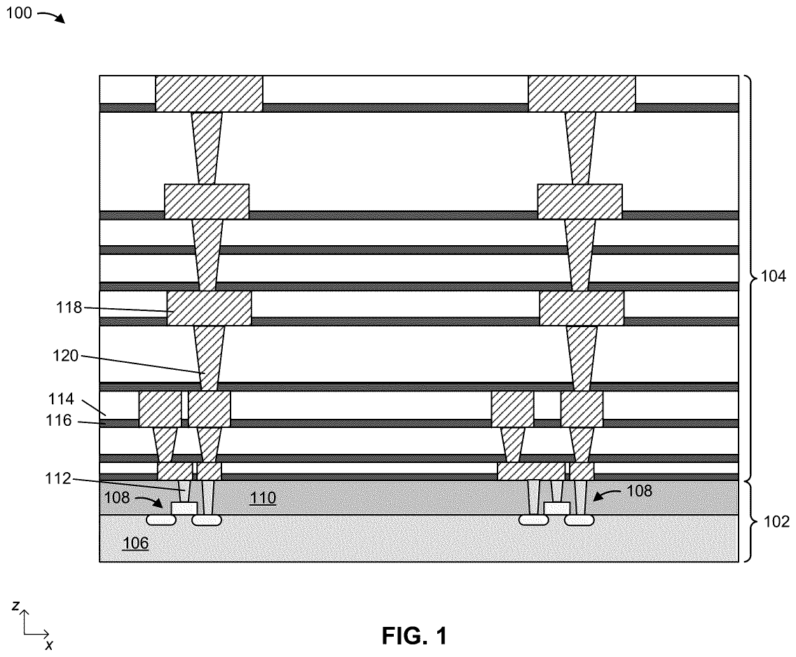

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1, the semiconductor device 100 may include a device layer 102 and an interconnect layer 104 above the device layer 102 in a z-direction in the semiconductor device 100. The device layer 102 may also be referred to as a frontend region or a front end of line (FEOL) region of the semiconductor device 100. The interconnect layer 104 may also be referred to as a backend region or a back end of line (BEOL) region of the semiconductor device 100.

The device layer 102 includes a bottom semiconductor layer 106. The bottom semiconductor layer 106 may correspond to a portion of a semiconductor wafer or another type of substrate on which the semiconductor device 100 is formed. In some implementations, the bottom semiconductor layer 106 is a bottom portion of the substrate, and additional semiconductor layers of the substrate are formed on the bottom semiconductor layer 106. In some implementations, the bottom semiconductor layer 106 corresponds to a substrate of the semiconductor device 100.

The bottom semiconductor layer 106 includes a silicon (Si) layer, a layer formed of a material including silicon, a III-V compound semiconductor material layer such as gallium arsenide (GaAs), a semiconductor layer of a silicon on insulator (SOI) substrate, or another type of semiconductor layer. The bottom semiconductor layer 106 may extend in an x-direction and/or in a y-direction in the semiconductor device 100.

Integrated circuit devices 108 may be included in and/or on the bottom semiconductor layer 106 in the device layer 102 of the semiconductor device 100. The integrated circuit devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the bottom semiconductor layer 106) of the semiconductor device 100.

In some implementations, one or more of the integrated circuit devices 108 include a high-voltage transistor (or a medium voltage transistor). “High-voltage transistor” refers to a transistor that is configured to operate at higher operating voltages (e.g., higher gate voltages, higher source/drain voltages) than low voltage transistors. As an example, a high-voltage transistor may be configured to operate in a drain voltage range of approximately 9 volts to approximately 36 volts, whereas a low-voltage transistor may be configured to operate in a drain voltage range of approximately 0 volts to approximately 1.8 volts. However, other values for these ranges are within the scope of the present disclosure.

In some implementations, a high-voltage transistor (or a medium voltage transistor) may include a laterally diffused (or laterally double diffused) metal-oxide semiconductor (LDMOS) transistor that has a drift region in which charge carriers are laterally diffused in the bottom semiconductor layer 106 to facilitate lateral distribution of an electric field between a gate structure and a source/drain region of the high-voltage transistor. The lateral diffusion of charge carriers in the drift region enables the high-voltage transistor to withstand higher gate and source/drain voltages (e.g., by increasing the breakdown voltage of the high-voltage transistor) than low voltage transistors.

In some implementations, a high-voltage transistor may include a vertically diffused (or vertically double diffused) metal-oxide semiconductor (vertical DMOS or VDMOS) transistor that has a drift region in which charge carriers are vertically diffused in the bottom semiconductor layer 106 to facilitate vertical distribution of an electric field between a gate structure and a source/drain region of the high-voltage transistor. The vertical diffusion of charge carriers in the drift region enables the high-voltage transistor to withstand higher gate and source/drain voltages while still achieving a smaller lateral footprint than an LDMOS transistor.

A dielectric layer 110 is included over the bottom semiconductor layer 106. The dielectric layer 110 includes an interlayer dielectric (ILD) layer, an etch stop layer (ESL), and/or another type of dielectric layer. The dielectric layer 110 includes dielectric material(s) that enable various portions of the bottom semiconductor layer 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the bottom semiconductor layer 106 and above the integrated circuit devices 108 in the z-direction in the semiconductor device 100. The integrated circuit devices 108 may be electrically coupled to the interconnect layer 104 by contact structures 112. In some implementations, an integrated circuit device 108 may be electrically coupled to gate contacts and source/drain contacts. The contact structures 112 may include contact plugs, vias, pillars, contact pads, and/or another type of electrically conductive contacts. The contact structures 112 may include one or more electrically conductive materials such as tungsten (W), cobalt (Co), ruthenium (Ru), titanium (Ti), an alloy thereof, a metal nitride that contains one or more metals, and/or another electrically conductive material. In some implementations, a liner is included between a contact structure 112 and the dielectric layer 110. The liner may include an adhesion liner, a barrier liner, and/or another type of liner, and may include liner materials such as tantalum (Ta), tantalum nitride (TaN), and/or titanium nitride (TiN), among other examples.

The interconnect layer 104 includes a plurality of dielectric layers (e.g., backend dielectric layers) that are arranged in a direction (e.g., the z-direction) that is approximately perpendicular to the bottom semiconductor layer 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104.

The interconnect layer 104 includes a plurality of conductive structures. One or more of the conductive structures are electrically coupled and/or physically coupled with one or more of the integrated circuit devices 108 (e.g., with the contact structures 112 of the integrated circuit devices 108) in the device layer 102. The conductive structures provide electrical routing that enables signals and/or power to be provided to and/or from the integrated circuit devices 108. The conductive structures may include a combination of metallization structures 118 and interconnect structures 120. The metallization structures 118 may include trenches, metallization layers, conductive traces, and/or other types of metallization structures. The interconnect structures 120 may include vias, plugs, interconnects, and/or another type of interconnect structures. The metallization structures 118 and the interconnect structures 120 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the metallization structures 118 and the interconnect structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 118 and the interconnect structures 120 of the interconnect layer 104 may be arranged in in a vertical manner (e.g., in the z-direction). In other words, a plurality of stacked metallization structures 118 and interconnect structures 120 extend between the device layer 102 and a top of the interconnect layer 104 to facilitate electrical signals and/or power to be routed between the device layer 102 and connection structures (not shown) of the semiconductor device 100. The plurality of stacked metallization structures 118 may be arranged in layers referred to as M-layers. For example, a metal-0 (M0) layer may located at the bottom of the interconnect layer 104 and may be directly coupled with the device layer 102 (e.g., with the contact structures 112 of the integrated circuit devices 108 in the device layer 102). A via-1 (V1) layer that includes one or more interconnect structures 120 may be included above the M0 layer. A metal-1 layer (M1) layer may be located above the V1 layer in the interconnect layer 104, a via-2 (V2) layer may be included above the M1 layer, a metal-2 layer (M2) layer may be located above the V2 layer, and so on. Additionally, via layers may be included between vertically arranged M-layers.

As indicated above, FIG. 1 is provided as an example. Other examples may differ from what is described with regard to FIG. 1.

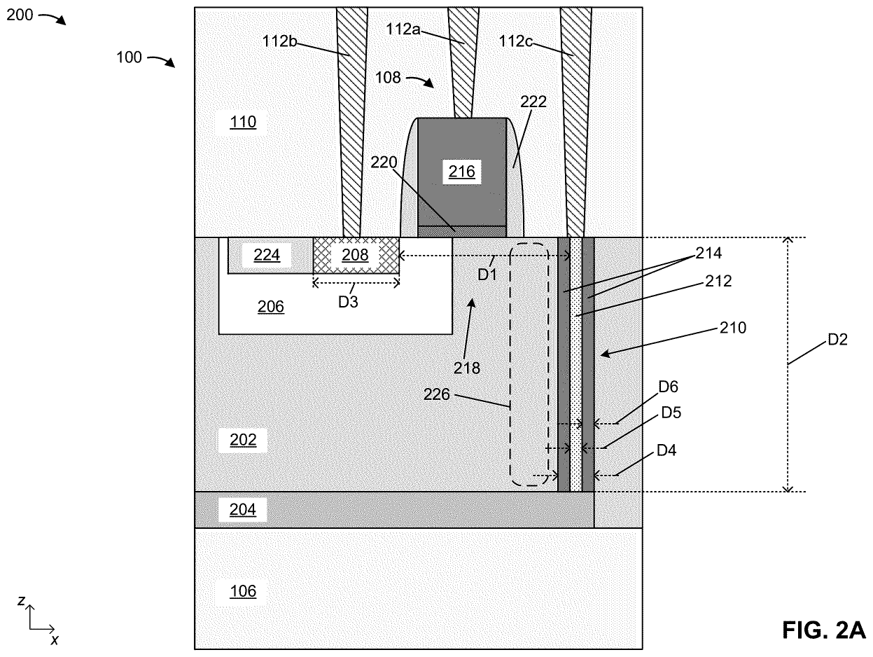

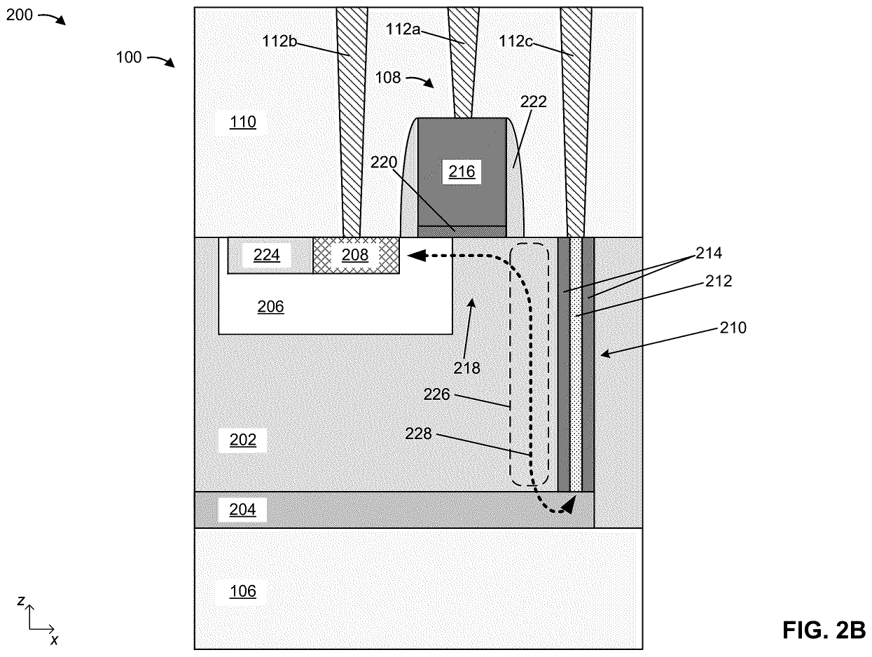

FIGS. 2A and 2B are diagrams of an example implementation 200 of an integrated circuit device 108 described herein. In the example implementation 200, the integrated circuit device 108 includes a VDMOS transistor (e.g., a VDMOS high-voltage transistor).

As shown in FIG. 2A, the integrated circuit device 108 may include (or may be included on) the bottom semiconductor layer 106 of the semiconductor device 100. The integrated circuit device 108 may include a doped semiconductor layer 202 above the bottom semiconductor layer 106, a doped buried semiconductor layer 204 in and/or between the doped semiconductor layer 202 and the bottom semiconductor layer 106, and a bulk region 206 in the doped semiconductor layer 202.

In some implementations, the doped semiconductor layer 202 may include a doped region of the bottom semiconductor layer 106 that is doped with one or more types of dopants, such as p-type dopants and/or n-type dopants. Alternatively, the doped semiconductor layer 202 may include a layer of doped semiconductor material (e.g., doped silicon, among other examples) that is epitaxially grown on the bottom semiconductor layer 106. In some implementations, the bottom semiconductor layer 106 may also be doped with one or more types of dopants. In these implementations, the bottom semiconductor layer 106 and the doped semiconductor layer 202 may be doped with the same dopant type (e.g., p-type dopants), or the bottom semiconductor layer 106 and the doped semiconductor layer 202 may be doped with different dopant types (e.g., the bottom semiconductor layer 106 may be doped with p-type dopants and the doped semiconductor layer 202 may be doped with n-type dopants).

The doped buried semiconductor layer 204 may also include a doped semiconductor material, and may include a same dopant type as the doped semiconductor layer 202 or a different dopant type. In some implementations, a dopant concentration in the doped buried semiconductor layer 204 is greater than a dopant concentration in the doped semiconductor layer 202. The greater dopant concentration in the doped buried semiconductor layer 204 promotes the flow of charge carriers downward into the doped semiconductor layer 202. In some implementations, a dopant concentration in the doped buried semiconductor layer 204 is approximately 1×10¹⁸ dopant atoms per cubic centimeter or greater. However, other values for the dopant concentration in the doped buried semiconductor layer 204 are within the scope of the present disclosure.

The bulk region 206 (which may also be referred to as a body region) may also include a doped semiconductor material. However, the bulk region 206 and the doped buried semiconductor layer 204 may include different dopant types. For example, the bulk region 206 may include one or more p-type dopants, and the doped buried semiconductor layer 204 may include one or more n-type dopants. However, other combinations of dopant types for the bulk region 206 and for the doped buried semiconductor layer 204 are within the scope of the present disclosure.

The integrated circuit device 108 may include a source/drain region 208 and a deep trench structure 210 that includes a vertical source/drain region 212 that is electrically insulated by dielectric isolation layers 214 on opposing sidewalls of the vertical source/drain region 212. The source/drain region 208 and the vertical source/drain region 212 may be spaced apart from each other by a portion of the dope semiconductor layer 202.

The integrated circuit device 108 may further include a gate structure 216 that is located laterally between the source/drain region 208 and the vertical source/drain region 212. The source/drain region 208 may be located on a first side (e.g., laterally adjacent to the first side) of the gate structure 216, and the vertical source/drain region 212 may be located on a second side (e.g., laterally adjacent to the second side) of the gate structure 216 opposing the first side. The source/drain region 208 may be located within the bulk region 206, and the vertical source/drain region 212 may be located within the doped semiconductor layer 202.

“Source/drain region” may refer to a source region, a drain region, or a combination of a source and drain region, depending on the context. In some implementations, the source/drain region 208 is a source region of the integrated circuit device 108, and the vertical source/drain region 212 is a drain region of the integrated circuit device 108 that is configured to operate at a relatively high voltage, such as up to approximately 36 volts.

The source/drain region 208 and the vertical source/drain region 212 may each include one or more doped regions or layers of doped material. In some implementations, the source/drain region 208 and the vertical source/drain region 212 may include the same dopant type. For example, the source/drain region 208 and the vertical source/drain region 212 may each include one or more p-type dopants such as boron (B) and/or gallium (Ga), among other examples. As another example, the source/drain region 208 and the vertical source/drain region 212 may each include one or more n-type dopants such as arsenic (A) and/or phosphorous (P), among other examples. In some implementations, the source/drain region 208 and the vertical source/drain region 212 include different dopant types. For example, the source/drain region 208 may include one or more p-type dopants, and the vertical source/drain region 212 may include one or more n-type dopants. In some implementations, a dopant concentration in the vertical source/drain region 212 is approximately 1×10¹⁸ dopant atoms per cubic centimeter or greater. However, other values for the dopant concentration in the vertical source/drain region 212 are within the scope of the present disclosure.

In some implementations, the source/drain region 208 and the vertical source/drain region 212 include the same material. For example, the source/drain region 208 and the vertical source/drain region 212 may each include polysilicon (e.g., that is doped with the same or different dopant types). In some implementations, the source/drain region 208 and the vertical source/drain region 212 include different materials. For example, the source/drain region 208 may include silicon (Si) (e.g., that is doped with one or more dopant types), and the vertical source/drain region 212 may include polysilicon (e.g., that is doped with one or more dopant types).

As shown in FIG. 2A, the vertical source/drain region 212 is an elongated structure that extends vertically (or primarily vertically) in the doped semiconductor layer 202. The vertical source/drain region 212 is a “vertical” source/drain region in that the vertical source/drain region 212 is elongated structure in the z-direction in the doped semiconductor layer 202. In some implementations, the vertical source/drain region 212 may extend from a top surface of the doped semiconductor layer 202 down to the doped buried semiconductor layer 204. Thus, the bottom of the vertical source/drain region 212 may be on and in physical contact with the doped buried semiconductor layer 204.

The vertical source/drain region 212 may correspond to a doped insert or doped semiconductor insert that is sandwiched between opposing dielectric isolation layers 214. The dielectric isolation layers 214 may include one or more dielectric materials such as a silicon oxide (SiOₓ such as SiO₂), a silicon nitride (SiₓN_{y} such as Si₃N₄), and/or another suitable dielectric material. The dielectric material of the dielectric isolation layers 214 may be omitted from the bottom of the deep trench structure 210 so that the doped buried semiconductor layer 204 and the vertical source/drain region 212 can be coupled (e.g., electrically connected, physically connected) and so that charge carriers can flow between the doped buried semiconductor layer 204 and the vertical source/drain region 212.

Each of the dielectric isolation layers 214 may correspond to a dielectric isolation layer segment on a sidewall of vertical source/drain region 212. For example, a first dielectric isolation layer 214 may correspond to a first dielectric isolation layer segment on a first sidewall of the vertical source/drain region 212 (e.g., a sidewall facing the source/drain region 208, and a second dielectric isolation layer 214 may correspond to a second dielectric isolation layer segment on a second sidewall of the vertical source/drain region 212 (e.g., a sidewall facing away from the source/drain region 208) opposing the first sidewall. The dielectric isolation layer segments extend along the height of the source/drain region 212 (e.g., along the height of the elongated structure) primarily in the z-direction. The dielectric isolation layers 214 (e.g., the dielectric isolation layer segments) on opposing sidewalls of the vertical source/drain region 212 may be non-continuous and spaced apart from each other by the vertical source/drain region 212.

The gate structure 216 may be located on the doped semiconductor layer 202. The gate structure 216 may be located laterally between the source/drain region 208 and the vertical source/drain region 212 in the x-direction. Thus, the top of the vertical source/drain region 212 (e.g., the doped insert of the deep trench structure 210) masy be lower in the semiconductor device 100 than a bottom of the gate structure 216. The region in the doped semiconductor layer 202 under the gate structure 216 between the source/drain region 208 and the vertical source/drain region 212 may be referred to as a channel region 218 of the integrated circuit device 108. An electrical bias may be selectively applied to the gate structure 216 to selectively control the electrical conductivity of the channel region 218 using an electric field. In this way, charge carriers may selectively flow between the source/drain region 208 and the vertical source/drain region 212 based on the electrical conductivity of the channel region 218. In some implementations, the gate structure 216 includes a polysilicon gate. In some implementations, the gate structure 216 includes a metal gate and includes one or more metal materials such as tungsten (W), titanium (Ti), titanium aluminum (TiAl), and/or other suitable metal materials.

A gate dielectric layer 220 may be included on the doped semiconductor layer 202 between the doped semiconductor layer 202 and the gate structure 216. Thus, the gate dielectric layer 220 is also located laterally between the source/drain region 208 and the vertical source/drain region 212 in the x-direction. In some implementations, a portion of the gate dielectric layer 220 is located on the bulk region 206 and another portion is included on the doped semiconductor layer 202. The gate dielectric layer 220 may provide electrical isolation between the gate structure 216 and the doped semiconductor layer 202, which enables an electrical bias (e.g., a voltage) to be applied to the gate structure 216 to cause an electric field to be generated in the channel region 218. In some implementations, the gate dielectric layer 220 may include a low dielectric constant (low-k) dielectric material such as a silicon oxide (SiOₓ such as SiO₂). Additionally and/or alternatively, the gate dielectric layer 220 may include a high dielectric constant (high-k) dielectric material (e.g., a dielectric material having a dielectric constant that is greater than approximately 3.9) such as a silicon nitride (SiₓN_{y} such as Si₃N₄), a hafnium oxide (HfOₓ such as HfO₂), and/or aluminum oxide (AlₓO_{y} such as Al₂O₃), among other examples.

One or more sidewall spacers 222 may be included over and/or on sidewalls of the gate structure 216. The sidewall spacers 222 may include a silicon oxycarbide (SiOC), a nitrogen free SiOC, or another suitable dielectric material. The sidewall spacers 222 may have a curved or rounded outer surface as a result of a directional (e.g., vertical) etch technique that is used to form the sidewall spacers 222.

A body implant region 224 may be included in the bulk region 206 next to the source/drain region 208. The body implant region 224 and the source/drain region 208 may be doped with opposing dopant types (e.g., the source/drain region 208 may be doped with n-type dopants and the body implant region 224 may be doped with p-type dopants). An electrical bias may be applied to the body implant region 224 to create a body bias in the bulk region 206 to compensate for shifts or changes in the threshold voltage (Vₜ) of the integrated circuit device 108.

As further shown in FIG. 2A, a vertical drift region 226 may correspond to a portion of the channel region 218 that extends vertically along the deep trench structure 210 (e.g., that extends vertically along the vertical source/drain region 212) between the gate structure 216 and the vertical source/drain region 212. During operation of the integrated circuit device 108, a depletion region may be formed in the channel region 218, including in the vertical drift region 226. In the depletion region, the magnitude (or intensity) of an electric field formed in the channel region 218 may be distributed between the top of the vertical source/drain region 212 near the gate structure 216 and the bottom of the vertical source/drain region 212 near the doped buried semiconductor layer 204. This reduces the peak magnitude of the electric field between the top of the vertical source/drain region 212 near the gate structure 216, and the bottom of the vertical source/drain region 212 near the doped buried semiconductor layer 204 so that the integrated circuit device 108 can achieve higher breakdown voltages.

As further shown in FIG. 2A, the dielectric layer 110 may be included over the integrated circuit device 108. A contact structure 112a (e.g., a gate contact) may be included in the one or more dielectric layers and may be electrically connected and/or physically connected with the gate structure 216, and contact structures 112b and 112c (e.g., source/drain contacts) may be included in the dielectric layer 110 and may be electrically connected and/or physically connected with the source/drain region 208 and the vertical source/drain region 212, respectively. The contact structure 112b may be located above and coupled to the source/drain region 208 and/or above the body implant region 224, and the contact structure 112c may be located above and coupled to the vertical source/drain region 212. The contact structures 112b and 112c may be located laterally adjacent to opposing sides of the gate structure 216 in the x-direction. In some implementations, the contact structure 112b is also electrically connected with the body implant region 224, which enables a source-body voltage (V_{SB}) to be applied to both the source/drain region 208 and the body implant region 224.

In some implementations, metal silicide layers may be included on the source/drain region 208 and/or on the vertical source/drain region 212 of the integrated circuit device 108. The metal silicide layers may each include a titanium silicide (TiSi), a ruthenium silicide (RuSi), and/or another type of metal silicide material. The metal silicide layers may provide a transition between the semiconductor material of the source/drain region 208 and the metal material of the contact structure 112b, and/or between the semiconductor material (e.g., the doped polysilicon material) of the vertical source/drain region 212 and the metal material of the contact structure 112c. The metal silicide layers enable a low contact resistance to be achieved between the source/drain region 208 and the contact structure 112b, and/or between the vertical source/drain region 212 and the contact structure 112c.

As further shown in FIG. 2A, the integrated circuit device 108 may have one or more dimensions. An example dimension D1 may correspond to a lateral distance (e.g., in the x-direction) between the source/drain region 208 and the vertical source/drain region 212. Because the vertical drift region 226 extends vertically in the doped semiconductor layer 202 as opposed to horizontally, the lateral distance between the source/drain region 208 and the vertical source/drain region 212 may be less than if the integrated circuit device 108 included a horizontal drift region. For example, the lateral distance between the source/drain region 208 and the vertical source/drain region 212 may be included in a range of approximately 2 microns to approximately 4 microns regardless of voltage rating, whereas an integrated circuit device that includes a horizontal drift region may have a lateral distance between source/drain regions in a range of greater than 4 microns and up to 20 microns or greater depending on the voltage rating for the integrated circuit device. However, other values and ranges for the lateral distance between the source/drain region 208 and the vertical source/drain region 212 are within the scope of the present disclosure.

Another example dimension D2 may correspond to a vertical (z-direction) height of the deep trench structure 210, which also corresponds to the vertical (z-direction) height of the vertical source/drain region 212. In some implementations, the vertical height of the deep trench structure 210 (and the vertical height of the vertical source/drain region 212) may be included in a range of approximately 5 microns to approximately 30 microns. If the vertical height of the deep trench structure 210 (and the vertical height of the vertical source/drain region 212) is less than approximately 5 microns, the vertical source/drain region 212 may be unable to be connected to the underlying doped buried semiconductor layer 204, which may result in increased resistance and/or increased current leakage in the integrated circuit device 108. If the vertical height of the deep trench structure 210 (and the vertical height of the vertical source/drain region 212) is greater than approximately 30 microns, the vertical source/drain region 212 may extend through the underlying doped buried semiconductor layer 204, which may result in increased resistance and/or increased current leakage in the integrated circuit device 108. However, other values and ranges other than approximately 5 microns to approximately 30 microns for the vertical height of the deep trench structure 210 (and the vertical height of the vertical source/drain region 212) are within the scope of the present disclosure.

Another example dimension D3 may correspond to a lateral length (or width) of the source/drain region 208 in the x-direction, another example dimension D4 may correspond to a lateral length (or width) of the overall deep trench structure 210 in the x-direction, another example dimension D5 may correspond to a lateral length (or width) of the vertical source/drain region 212 in the x-direction, and another example dimension D6 may correspond to a lateral length (or width) of a dielectric isolation layer 214 in the x-direction. Because the deep trench structure 210 and the vertical source/drain region 212 are elongated in the z-direction, the lateral length (or width) of the deep trench structure 210 in the x-direction and the lateral length (or width) of the vertical source/drain region 212 in the x-direction may both be less than the lateral length (or width) of the source/drain region 208 in the x-direction. The height of the deep trench structure 210 (and the vertical height of the vertical source/drain region 212) may be greater than the height of the source/drain region 208, and therefore the bottom surface of the vertical source/drain region 212 may be located at a lower vertical position in the doped semiconductor layer 202 than the vertical position of the bottom surface of the source/drain region 208.

In some implementations, the lateral length (or width) of the deep trench structure 210 in the x-direction (dimension D4) may be included in a range of approximately 2 microns to approximately 5 microns. If the lateral length (or width) of the deep trench structure 210 in the x-direction is less than approximately 2 microns, the electric field strength in the vertical drift region 226 may be too high and may result in breakdown of the dielectric isolation layers 214 and/or breakdown in the doped semiconductor layer 202. If the lateral length (or width) of the deep trench structure 210 in the x-direction is greater than approximately 5 microns, the lateral size of the deep trench structure 210 may result in reduced integrated circuit device density in the semiconductor device. However, other values and ranges other than approximately 2 microns to approximately 5 microns are within the scope of the present disclosure.

The lateral length (or width) of the vertical source/drain region 212 in the x-direction (dimension D5) may be across the vertical source/drain region 212 and across the dielectric isolation layers 214. In some implementations, the lateral length (or width) of the vertical source/drain region 212 in the x-direction (dimension D5) is included in a range of approximately 1 micron to approximately 2 microns. If the lateral length (or width) of the vertical source/drain region 212 in the x-direction is less than approximately 1 micron, the electric field strength in the vertical drift region 226 may be too high and may result in breakdown of the dielectric isolation layers 214 and/or breakdown in the doped semiconductor layer 202. If the lateral length (or width) of the vertical source/drain region 212 in the x-direction is greater than approximately 2 microns, the lateral size of the deep trench structure 210 may result in reduced integrated circuit device density in the semiconductor device. However, other values and ranges other than approximately 1 micron to approximately 2 microns are within the scope of the present disclosure.

In some implementations, the lateral length (or width) of a dielectric isolation layer 214 in the x-direction (dimension D6) may be included in a range of approximately 500 nanometers to approximately 1500 nanometers. If the lateral length (or width) of a dielectric isolation layer 214 in the x-direction is less than approximately 500 nanometers, the dielectric isolation layers 214 may not provide sufficient electrical isolation for the vertical source/drain region 212, resulting in increased electric field strength in the vertical drift region 226. If the lateral length (or width) of a dielectric isolation layer 214 in the x-direction is greater than approximately 1500 nanometers, the dielectric isolation layers 214 may occupy too large of area in the deep trench structure 210, resulting in insufficient space for the vertical source/drain region 212. However, other values and ranges other than approximately 500 nanometers to approximately 1500 nanometers are within the scope of the present disclosure.

In some implementations, an aspect ratio of the deep trench structure 210 (e.g., a ratio of the vertical (z-direction) height of the deep trench structure 210 to the lateral length (or width) of the deep trench structure 210 in the x-direction) is included in a range of approximately 3:1 to approximately 20:1. If the aspect ratio of the deep trench structure 210 is less than approximately 3:1, the vertical source/drain region 212 may be unable to be connected to the underlying doped buried semiconductor layer 204, which may result in increased resistance and/or increased current leakage in the integrated circuit device 108. If the aspect ratio of the deep trench structure 210 is greater than approximately 20:1, the vertical source/drain region 212 may extend through the underlying doped buried semiconductor layer 204, which may result in increased resistance and/or increased current leakage in the integrated circuit device 108. However, other values and ranges other than approximately 3:1 to approximately 20:1 for the aspect ratio of the deep trench structure 210 (and the vertical height of the vertical source/drain region 212) are within the scope of the present disclosure.

FIG. 2B illustrates an example charge carrier flow path 228 in the integrated circuit device 108. As shown in FIG. 2B, charge carriers may flow between the source/drain region 208 and the vertical source/drain region 212 through the channel region 218 under the gate structure 216. Moreover, charge carriers may flow along the vertical source/drain region 212 in the vertical drift region 226 between the top of the doped semiconductor layer 202 and the doped buried semiconductor layer 204. Charge carriers may flow through the doped buried semiconductor layer 204 and under the dielectric isolation layers 214 to the vertical source/drain region 212, and/or may flow from the vertical source/drain region 212 under dielectric isolation layers 214 to the doped buried semiconductor layer 204 and upward through the vertical drift region 226.

As indicated above, FIGS. 2A and 2B are provided as an example. Other examples may differ from what is described with regard to FIGS. 2A and 2B.

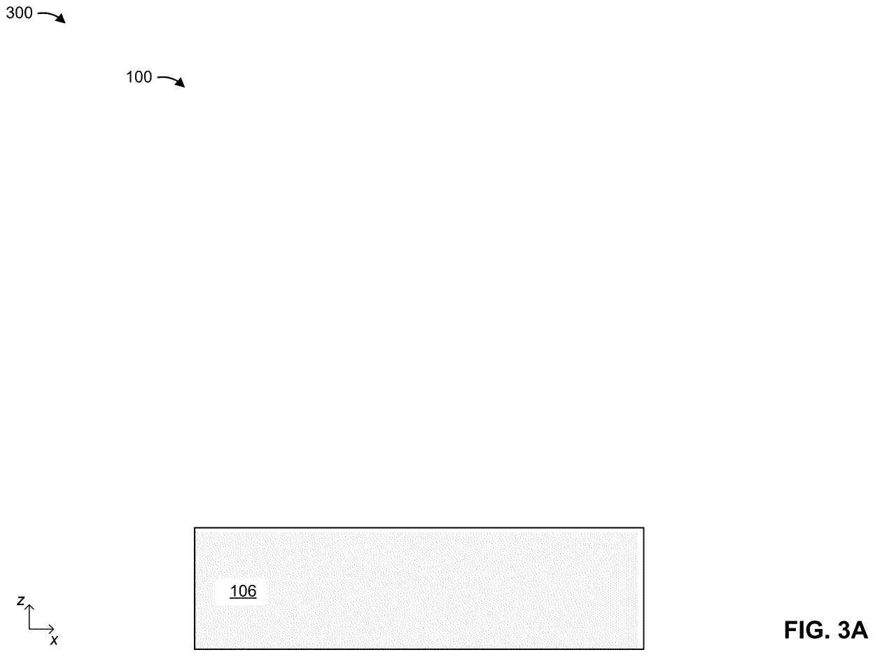

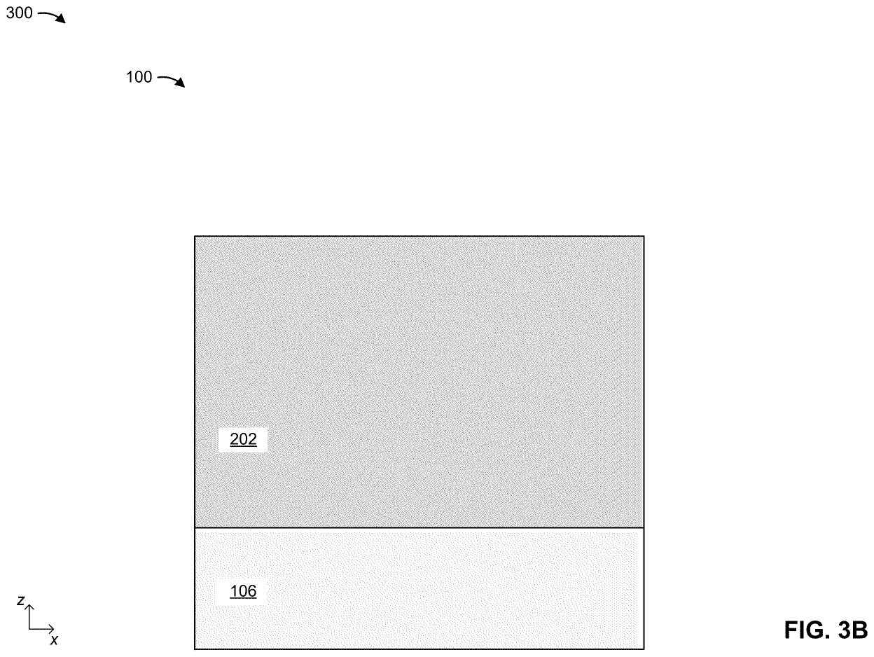

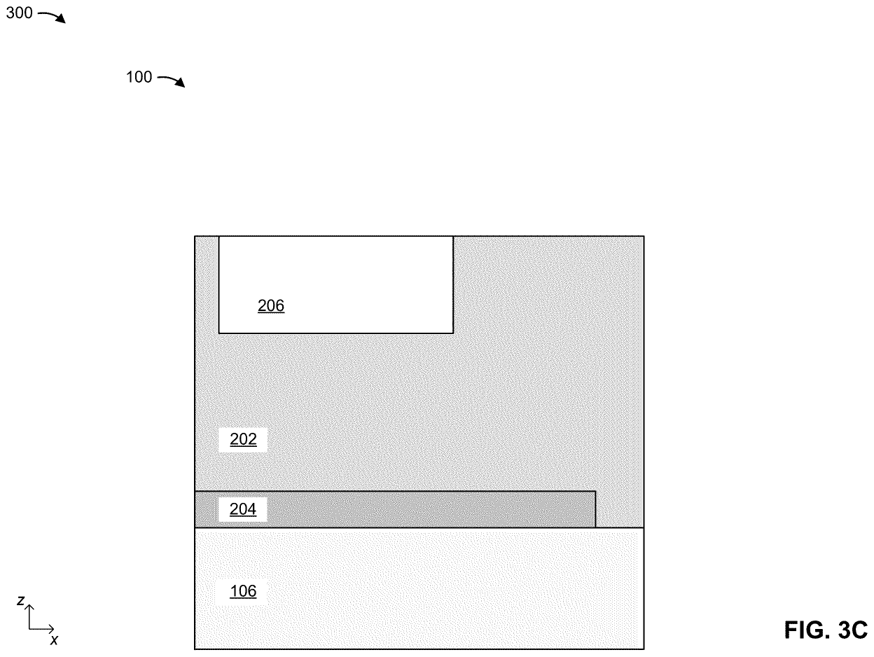

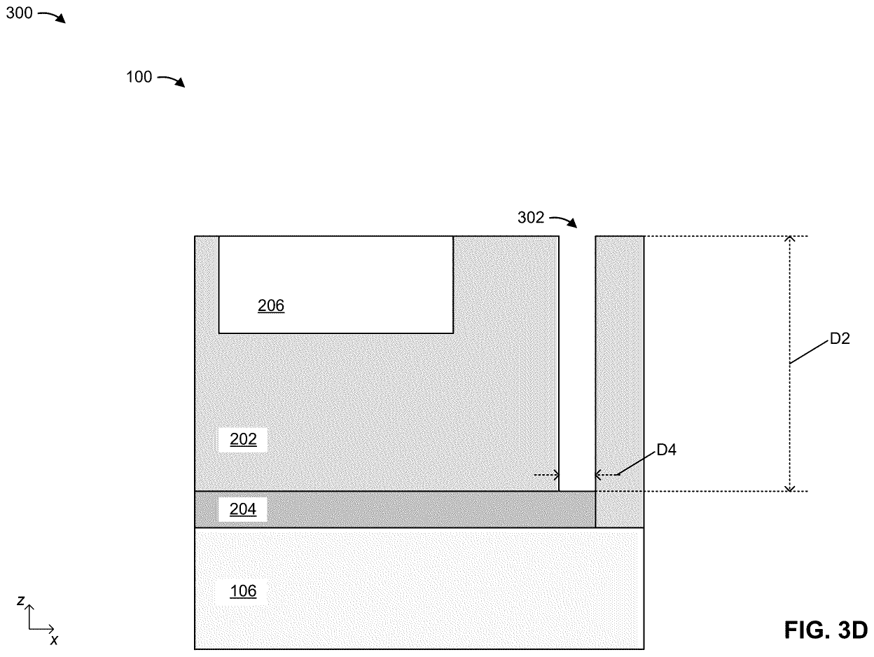

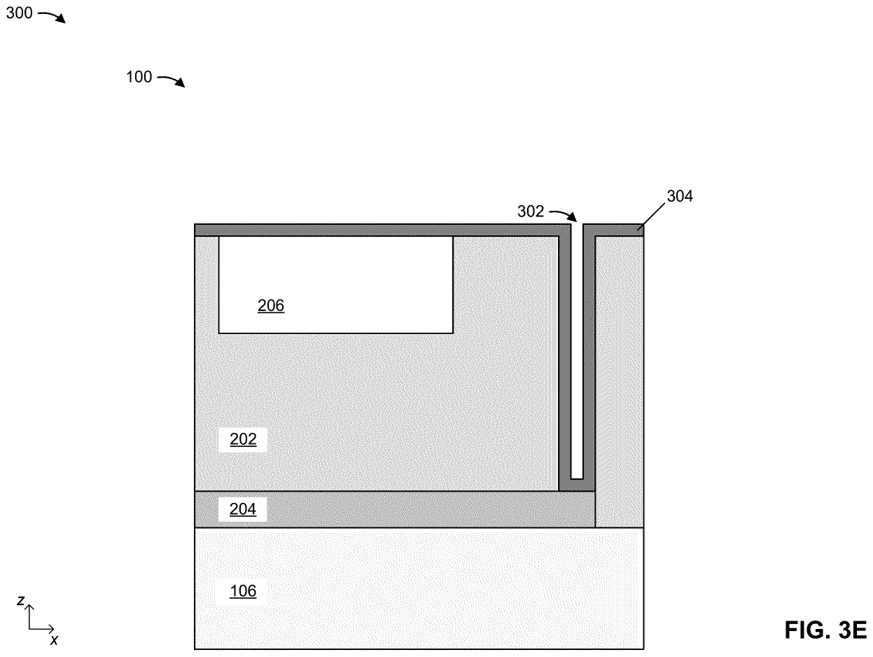

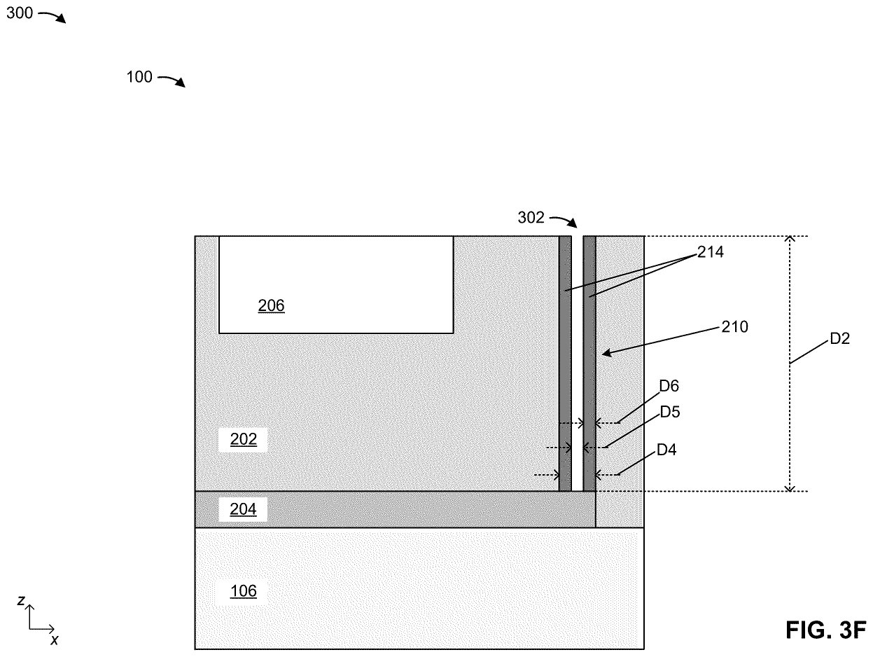

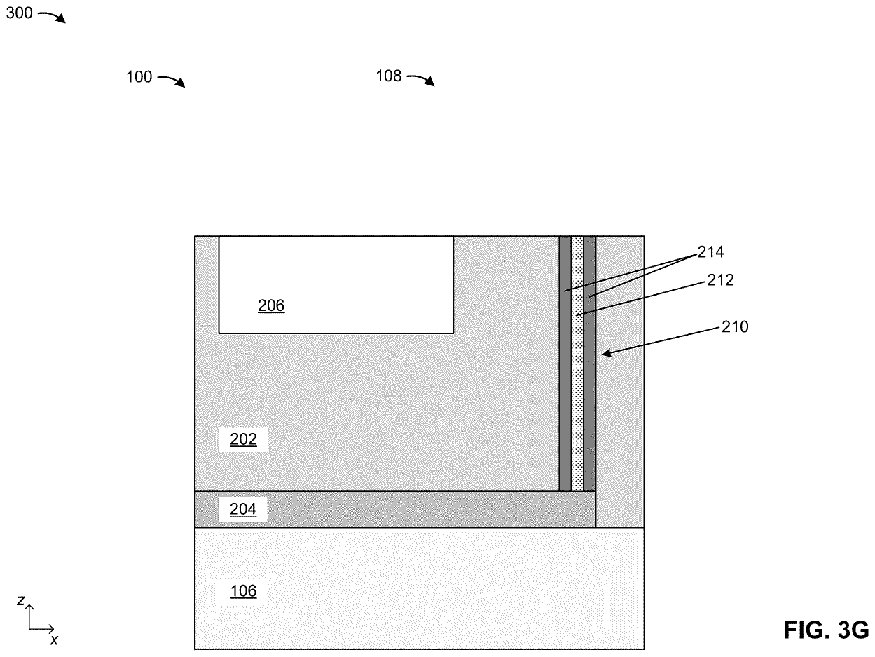

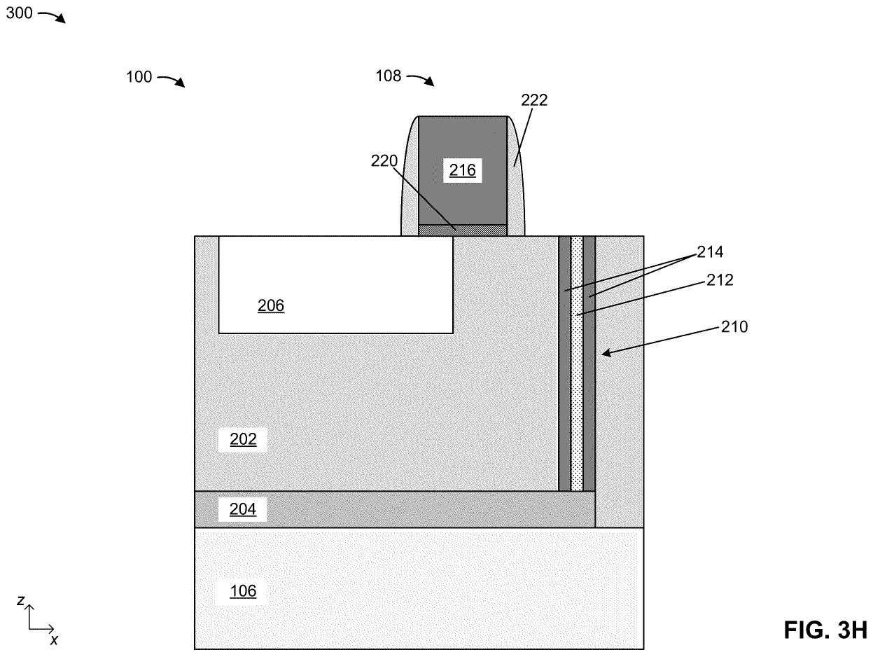

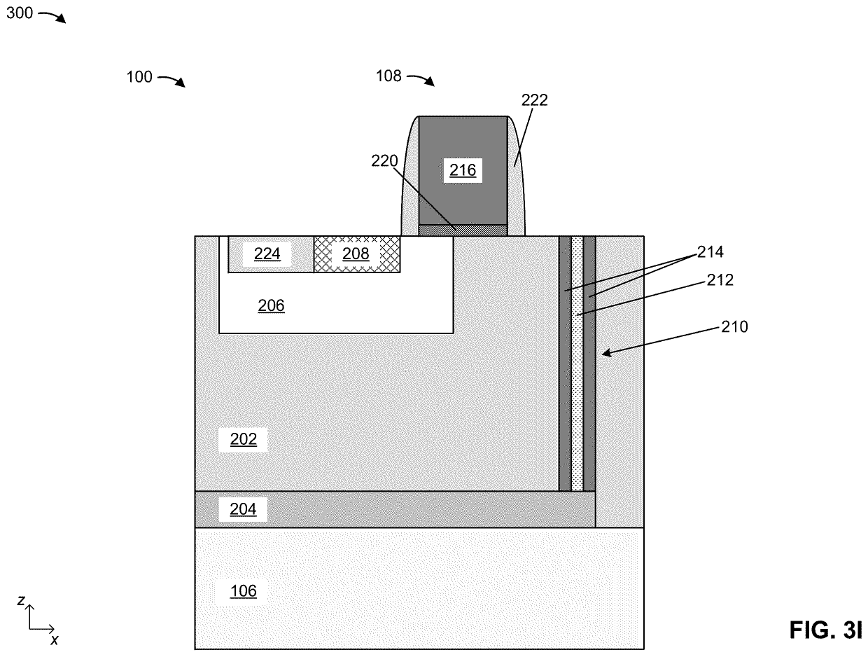

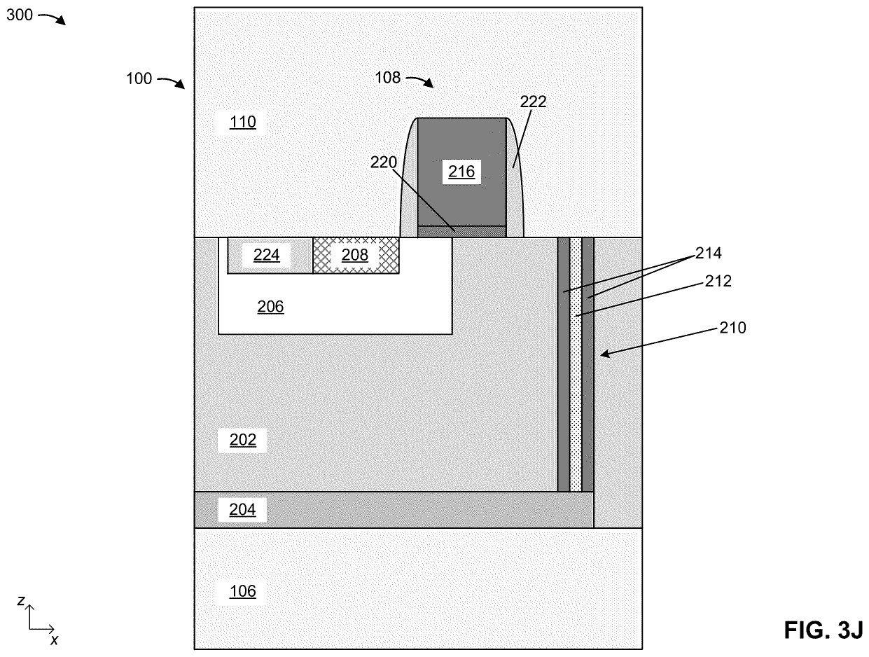

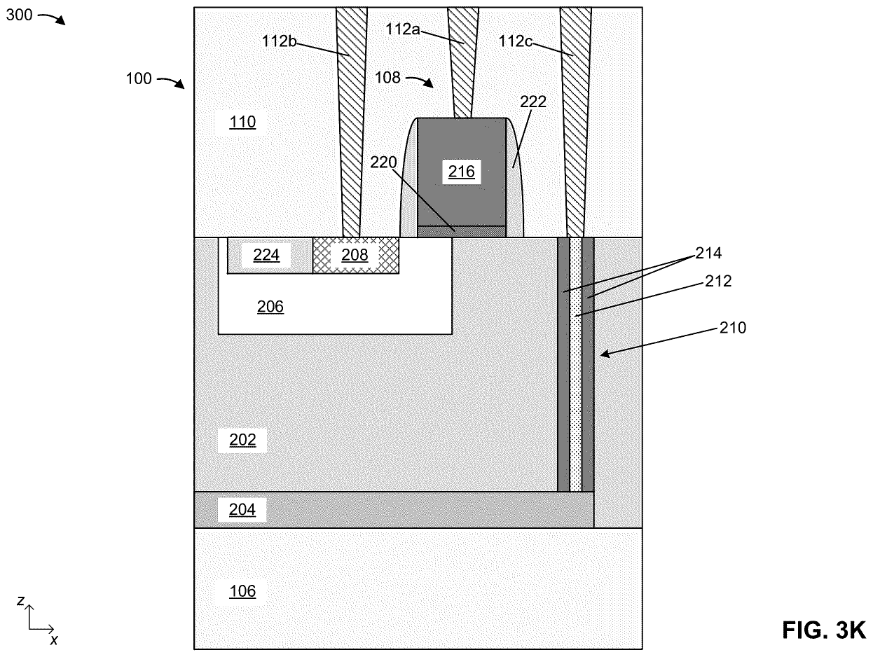

FIGS. 3A-3K are diagrams of an example implementation 300 of forming an integrated circuit device 108 that includes a vertical source/drain region 212 described herein. In some implementations, one or more of the operations described in connection with FIGS. 3A-3K may be performed using one or more semiconductor processing tools, such as a deposition tool, an exposure tool, a developer tool, an etch tool, an ion implantation tool, a planarization tool, and/or another suitable semiconductor processing tool.

Turning to FIG. 3A, one or more of the operations in the example implementation 300 may be performed in connection with the bottom semiconductor layer 106 of the semiconductor device 100. The bottom semiconductor layer 106 may be provided in the form of a semiconductor wafer or another type of substrate.

As shown in FIG. 3B, the doped semiconductor layer 202 may be formed above the bottom semiconductor layer 106. In some implementations, a deposition tool is used to form the doped semiconductor layer 202 by epitaxial growth, where atomic layers of semiconductor material are formed in a particular crystal structure.

As shown in FIG. 3C, the doped buried semiconductor layer 204 may be formed. In some implementations, an ion implantation tool is used to implant dopants (e.g., p-type dopants, n-type dopants) into the doped semiconductor layer 202 to form the doped buried semiconductor layer 204. In some implementations, the doped buried semiconductor layer 204 is formed prior to formation of the doped semiconductor layer 202, and the doped buried semiconductor layer 204 is formed by epitaxial growth.

As further shown in FIG. 3C, the doped buried semiconductor layer 204 may be formed. In some implementations, an ion implantation tool is used to implant dopants (e.g., p-type dopants, n-type dopants) into the doped semiconductor layer 202 to form the bulk region 206.

As shown in FIG. 3D, a recess 302 may be formed in the doped semiconductor layer 202. The recess 302 may extend downward into the doped semiconductor layer 202 to the underlying doped buried semiconductor layer 204. Thus, the doped buried semiconductor layer 204 may be exposed through the recess 302. The recess 302 may be formed to a high aspect ratio (e.g., a ratio of the vertical (z-direction) height of the recess 302 (dimension D2) to the lateral length (or width) of the recess 302 in the x-direction (dimension D4)) that is included in a range of approximately 3:1 to approximately 20:1. However, other values and ranges other than approximately 3:1 to approximately 20:1 for the aspect ratio of the recess 302 are within the scope of the present disclosure.

In some implementations, a pattern in a photoresist layer is used to etch the doped semiconductor layer 202 to form the recess 302. In these implementations, a deposition tool may be used to form the photoresist layer on the doped semiconductor layer 202 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the doped semiconductor layer 202 based on the pattern to form the recess 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the doped semiconductor layer 202 based on a pattern.

As shown in FIG. 3E, a dielectric layer 304 may be conformally deposited in the recess 302 such that the dielectric layer 304 conforms to the sidewalls and bottom surface of the recess 302. The dielectric layer 304 may also be formed over the top surface of the doped semiconductor layer 202. In some implementations, a deposition tool may be used to deposit the dielectric layer 304 using a conformal deposition technique such as chemical vapor deposition (CVD), atomic layer deposition (ALD), and/or another suitable conformal deposition technique. Additionally and/or alternatively, the dielectric layer 304 may be formed by oxidation (e.g., thermal oxidation) of the sidewalls and bottom surface of the recess 302.

As shown in FIG. 3F, the dielectric layer 304 may be trimmed to remove portions of the dielectric layer on the top surface of the doped semiconductor layer 202 and on the bottom surface of the recess 302. The remaining portions of the dielectric layer 304 correspond to the dielectric isolation layers 214 of the deep trench structure 210 on the sidewalls of the recess 302.

Each of the dielectric isolation layers 214 may correspond to a dielectric isolation layer segment on a sidewall of the recess 302. For example, a first dielectric isolation layer 214 may correspond to a first dielectric isolation layer segment on a first sidewall of the recess 302 (e.g., a sidewall facing the bulk region 206, and a second dielectric isolation layer 214 may correspond to a second dielectric isolation layer segment on a second sidewall of the recess 302 (e.g., a sidewall facing away from the bulk region 206) opposing the first sidewall. Trimming the bottom portion of the dielectric layer 304 at the bottom of the recess 302 results in the dielectric isolation layers 214 (e.g., the dielectric isolation layer segments) on opposing sidewalls of the recess 302 being non-continuous and spaced apart from each other.

In some implementations, an etch tool may be used to perform an anisotropic etch operation in which vertical etching is used to remove the portions of the dielectric layer on the top surface of the doped semiconductor layer 202 and on the bottom surface of the recess 302.

As further shown in FIG. 3F, the dielectric isolation layers 214 may be formed to a lateral length (or width) of a dielectric isolation layer 214 in the x-direction (dimension D6) that may be included in a range of approximately 500 nanometers to approximately 1500 nanometers. A remaining lateral width of the recess 302 after formation of the dielectric isolation layer 214 (dimension D5) may be included in a range of approximately 1 micron to approximately 2 microns. However, other values for these ranges are within the scope of the present disclosure.

As shown in FIG. 3G, the vertical source/drain region 212 of the integrated circuit device 108 may be formed in the remaining area in the recess 302 such that the vertical source/drain region 212 lands on the doped buried semiconductor layer 204. In some implementations, a deposition tool is used to deposit the polysilicon material of the vertical source/drain region 212 by CVD, ALD, and/or another suitable deposition technique, which may enable the vertical source/drain region 212 to be formed by lower cost and/or lower complexity processes compared to epitaxial growth that might otherwise be used if the vertical source/drain region 212 were formed of silicon (Si).

As shown in FIG. 3H, the gate dielectric layer 220 may be formed on the doped semiconductor layer 202 and a gate structure 216 may be formed on the gate dielectric layer 220. A deposition tool may be used to deposit the gate dielectric layer 220 using a physical vapor deposition (PVD) technique, a CVD technique, an ALD technique, and/or another suitable deposition technique. In some implementations, a planarization tool may be used to perform a planarization operation (e.g., a chemical-mechanical planarization (CMP) operation) to planarize the gate dielectric layer 220. A deposition tool may be used to deposit the gate structure 216 using a PVD technique, a CVD technique, an ALD technique, an electroplating technique, and/or another suitable deposition technique. In some implementations, the gate structure 216 is planarized using a planarization tool. The gate structure 216 may be planarized using a CMP technique and/or another suitable planarization technique.

As further shown in FIG. 3H, the sidewall spacers 222 may be deposited (e.g., using a deposition tool) on the sidewalls of the gate structure 216 using a CVD technique, an ALD technique, a PVD technique, and/or another type of deposition technique. In some implementations, a spacer layer is blanket deposited over the semiconductor device 100 and then etched back to define the sidewall spacers 222.

As shown in FIG. 3I, the source/drain region 208 may be formed in the bulk region 206 in the doped semiconductor layer 202. Moreover, the body implant region 224 may be formed in the bulk region 206 in the doped semiconductor layer 202 next to the source/drain region 208. In some implementations, the source/drain region 208 may be formed by doping portions of the bulk region 206. An ion implantation tool may be used to implant dopant ions into the bulk region 206 to form the source/drain region 208. Additionally and/or alternatively, another doping technique (such as diffusion) may be used to form the source/drain region 208.

In some implementations, the source/drain region 208 is formed by epitaxially growing the source/drain region 208 in a recess in the bulk region 206. An etch tool may be used to etch the bulk region 206 to form the recess. The etch operation may be referred to as a strained source/drain (SSD) etch operation, and the recesses may be referred to as strained source/drain recesses. In some implementations, the etch operation includes a plasma etch technique, a wet chemical etch technique, and/or another type of etch technique.

A deposition tool may be used to form the source/drain region 208 in the recess. The deposition tool may be used to form the source/drain region 208 by epitaxial growth, in which layers of the epitaxial material are deposited in the recesses such that the layers of semiconductor material are formed by epitaxial growth in a particular crystalline orientation.

The material (e.g., silicon (Si), gallium (Ga), or another type of semiconductor material) that is used to form the source/drain region 208 may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation.

As shown in FIG. 3J, the dielectric layer 110 may be formed over and/or on the integrated circuit device 108. A deposition tool may be used to deposit the dielectric layer 110 using a PVD technique, a CVD technique, an ALD technique, an oxidation technique, and/or another suitable deposition technique. In some implementations, a planarization tool is used to perform a CMP operation to planarize the dielectric layer 110.

As shown in FIG. 3K, the contact structure 112a (e.g., a gate contact) may be formed over the gate structure 216 such that the contact structure 112a lands on the gate structure 216. The contact structure 112b (e.g., a source/drain contact) may be formed over the source/drain region 208 such that the contact structure 112b lands on the source/drain region 208. The contact structure 112c (e.g., a source/drain contact) may be formed over the vertical source/drain region 212 such that the contact structure 112c lands on the vertical source/drain region 212.

The contact structures 112a-112c may be formed in recesses in the dielectric layer 110. For example, a recess may be formed over the source/drain region 208 to expose the source/drain region 208 through the recess. As another example, a recess may be formed over the vertical source/drain region 212 to expose the vertical source/drain region 212 through the recess. As another example, a recess may be formed over the gate structure 216 to expose the gate structure 216 through the recess.

In some implementations, a pattern in a photoresist layer is used to form the recesses. In these implementations, a deposition tool may be used to form the photoresist layer over the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch through the dielectric layer 110 to form the recesses. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses based on a pattern.

A deposition tool may be used to deposit the contact structures 112a-112c in the recesses using a CVD technique, a PVD technique, an ALD technique, an electroplating technique, and/or another suitable deposition technique. The contact structures 112a-112c may be deposited in one or more deposition operations. In some implementations, a seed layer is first deposited, and the contact structures 112a-112c are deposited on the seed layer. In some implementations, a liner is deposited in the recesses, and the contact structures 112a-112c are deposited on the liner in the recesses. The liner may include a barrier liner, an adhesion liner, and/or another suitable liner. Examples of liner materials include tantalum nitride (TaN), titanium nitride (TiN), and/or other suitable liner materials. In some implementations, a planarization tool is used to perform a planarization operation (e.g., a CMP operation) to planarize the contact structures 112a-112c after the contact structures 112a-112c are deposited.

As indicated above, FIGS. 3A-3K are provided as an example. Other examples may differ from what is described with regard to FIGS. 3A-3K.

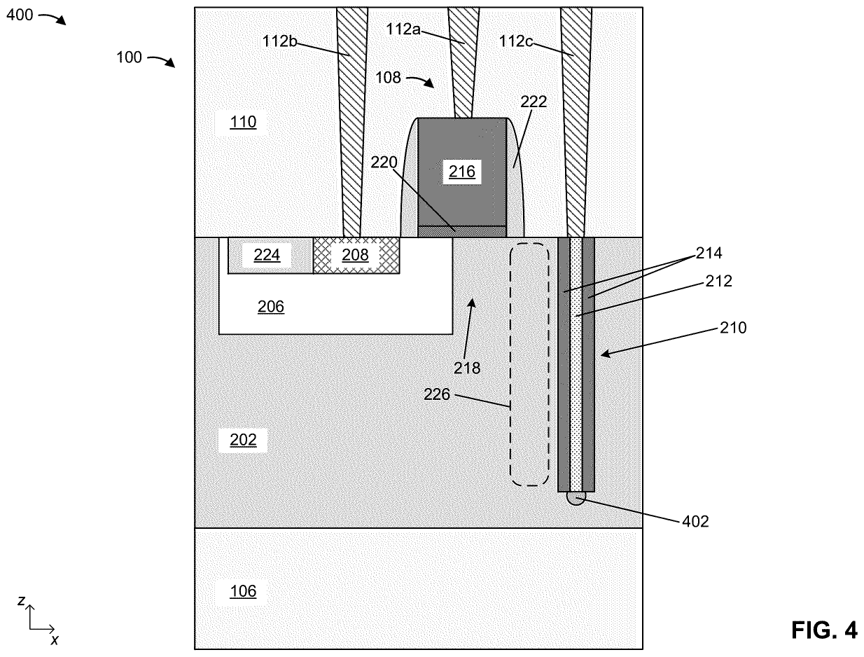

FIG. 4 is a diagram of an example implementation 400 of an integrated circuit device 108 described herein. In the example implementation 200, the integrated circuit device 108 includes a VDMOS transistor. As shown in FIG. 4, the example implementation 400 of the integrated circuit device 108 includes a similar combination and arrangement of layers and/or structures as the example implementation 200 of the integrated circuit device 108 in FIGS. 2A and 2B. However, in the example implementation 400 of the integrated circuit device 108, the doped buried semiconductor layer 204 is omitted. Instead, a doped implant region 402 is included under the vertical source/drain region 212. The doped implant region 402 may promote the flow of charge carriers between the vertical source/drain region 212 and the vertical drift region 226.

The bottom of the vertical source/drain region 212 may be in contact with the doped implant region 402. Unlike the doped buried semiconductor layer 204, the doped implant region 402 does not extend under the vertical drift region 226 or the gate structure 216. The doped implant region 402 may include a semiconductor material that is doped with the same dopant type as the vertical source/drain region 212. For example, the doped implant region 402 may include silicon (Si) doped with one or more n-type dopants, and the vertical source/drain region 212 may include polysilicon doped with one or more n-type dopants. In some implementations, the doped implant region 402 is an extension of the vertical source/drain region 212, and also includes polysilicon doped with one or more types of dopants. In some implementations, a dopant concentration in the doped implant region 402 is approximately 1×10¹⁸ dopant atoms per cubic centimeter or greater. However, other values for the dopant concentration in the doped implant region 402 are within the scope of the present disclosure.

As indicated above, FIG. 4 is provided as an example. Other examples may differ from what is described with regard to FIG. 4.

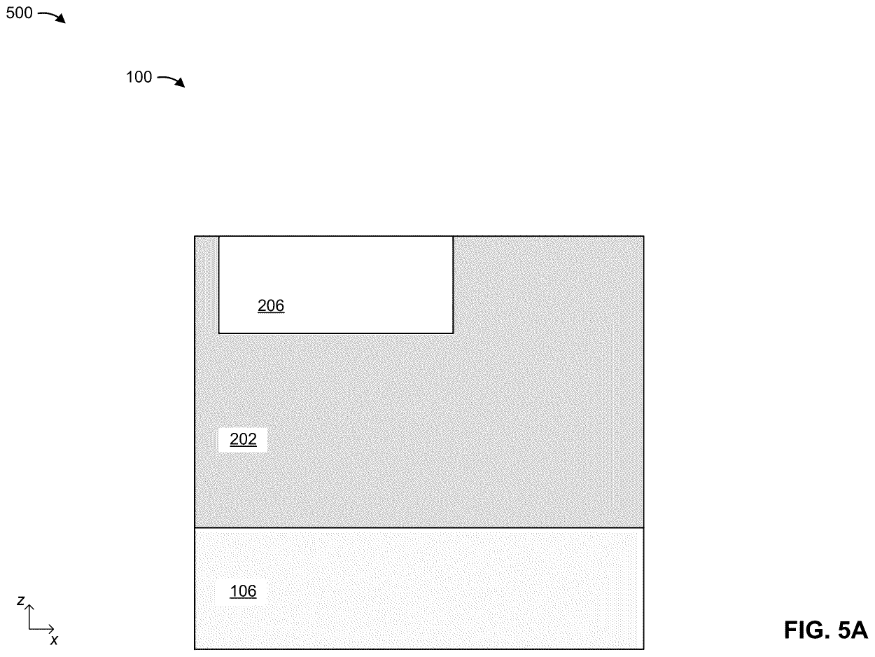

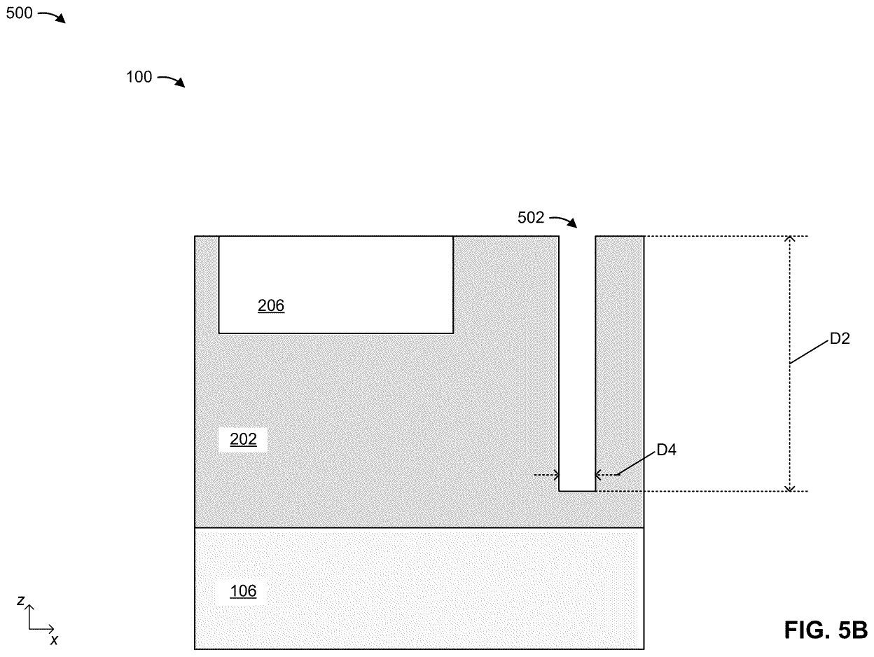

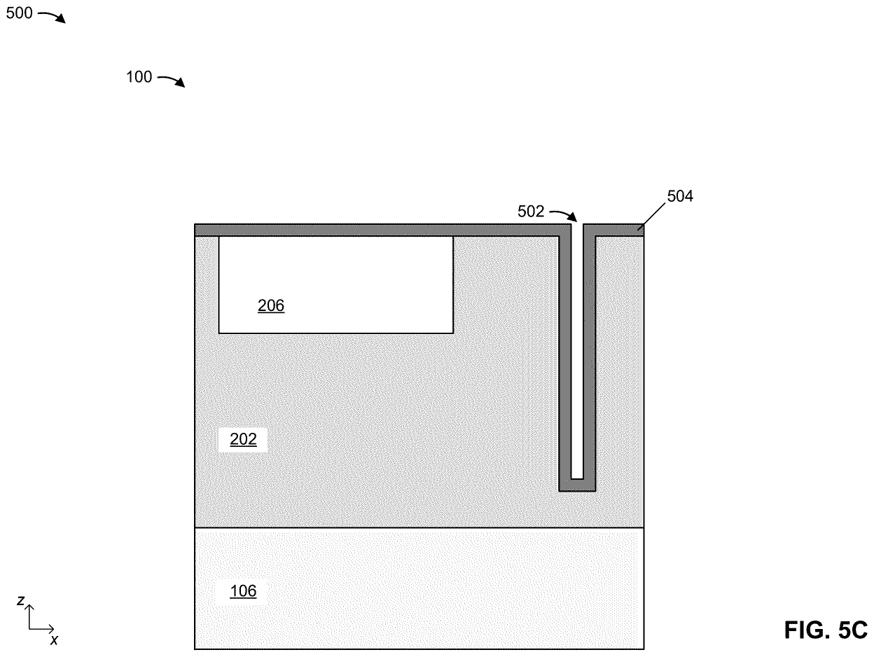

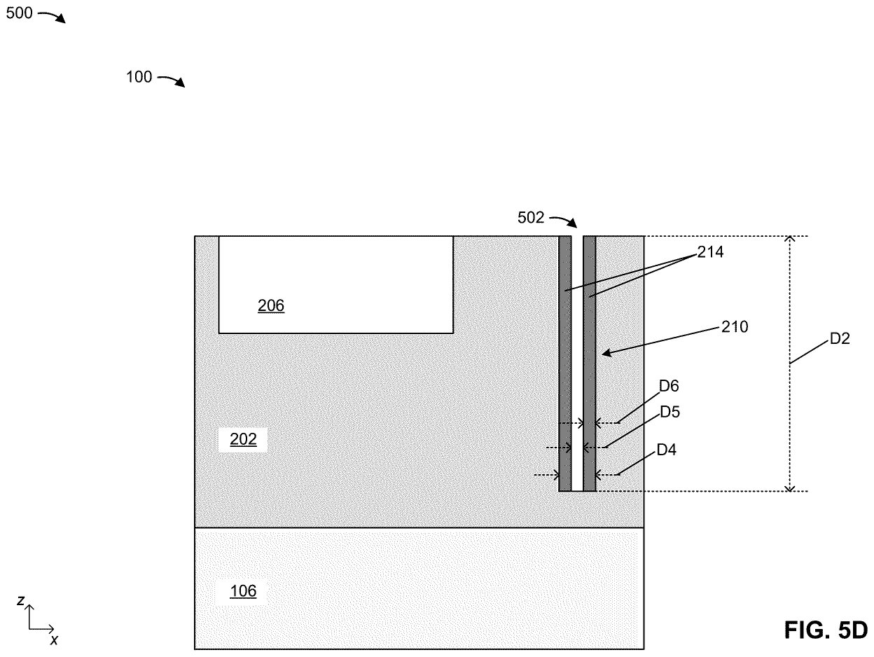

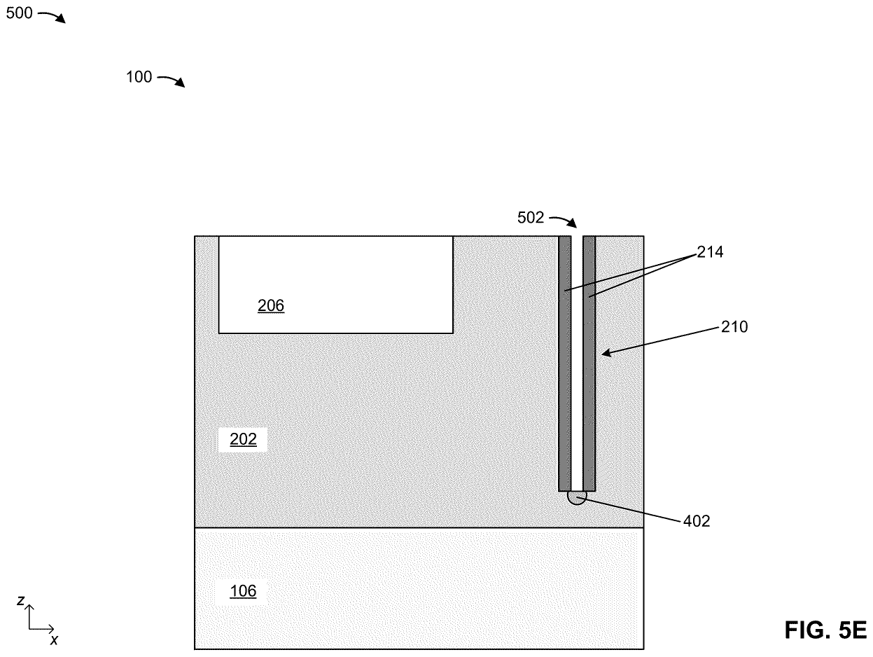

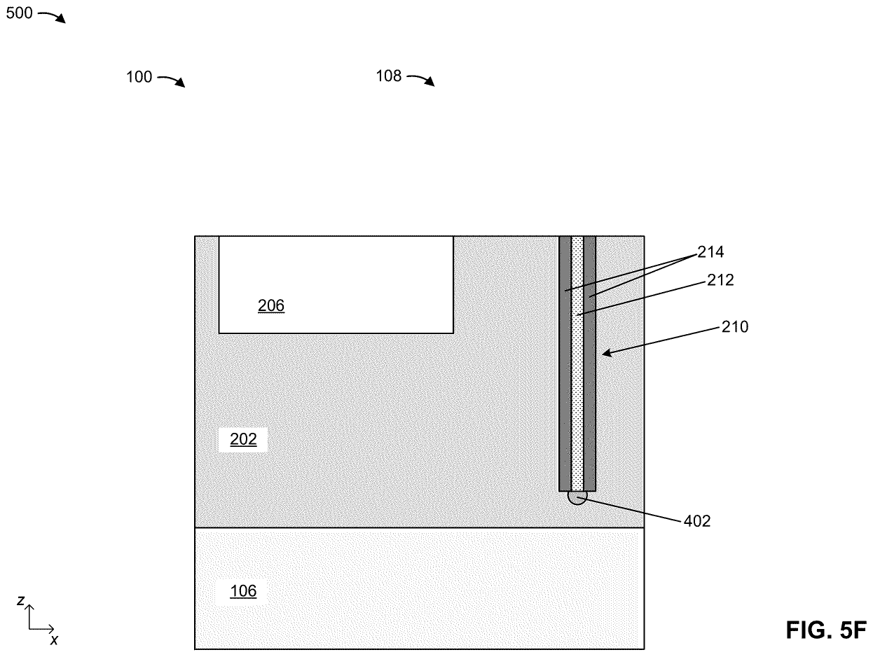

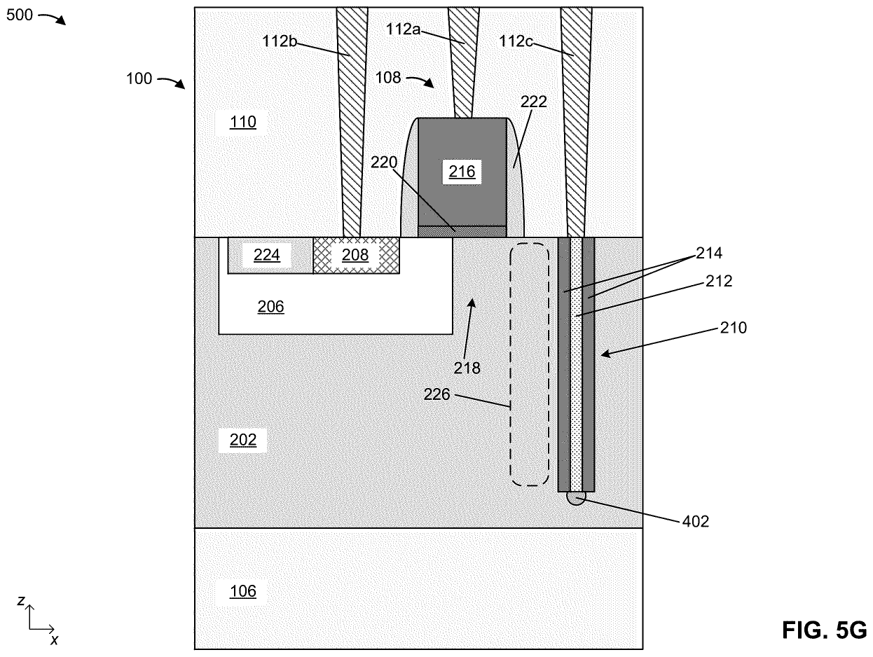

FIGS. 5A-5G are diagrams of an example implementation 500 of forming an integrated circuit device 108 that includes a vertical source/drain region 212 described herein. In some implementations, one or more of the operations described in connection with FIGS. 5A-5G may be performed using one or more semiconductor processing tools, such as a deposition tool, an exposure tool, a developer tool, an etch tool, an ion implantation tool, a planarization tool, and/or another suitable semiconductor processing tool.

As shown in FIG. 5A, the doped semiconductor layer 202 and the bulk region 206 may be formed above the bottom semiconductor layer 106 of the semiconductor device 100. The

doped semiconductor layer 202 and the bulk region 206 may be formed in a similar manner as described in connection with FIGS. 3B and 3C.

As shown in FIG. 5B, a recess 502 may be formed in the doped semiconductor layer 202. The recess 502 may be formed in a similar manner as described in connection with FIG. 3D for the recess 302. The recess 502 may be formed to a high aspect ratio (e.g., a ratio of the vertical (z-direction) height of the recess 502 (dimension D2) to the lateral length (or width) of the recess 502 in the x-direction (dimension D4)) that is included in a range of approximately 3:1 to approximately 20:1. However, other values and ranges other than approximately 3:1 to approximately 20:1 for the aspect ratio of the recess 502 are within the scope of the present disclosure.

As shown in FIG. 5C, a dielectric layer 504 may be conformally deposited in the recess 502 such that the dielectric layer 504 conforms to the sidewalls and bottom surface of the recess 502. The dielectric layer 504 may also be formed over the top surface of the doped semiconductor layer 202. In some implementations, a deposition tool may be used to deposit the dielectric layer 504 using a conformal deposition technique such as CVD, ALD, and/or another suitable conformal deposition technique. Additionally and/or alternatively, the dielectric layer 504 may be formed by oxidation (e.g., thermal oxidation) of the sidewalls and bottom surface of the recess 502.

As shown in FIG. 5D, the dielectric layer 504 may be trimmed to remove portions of the dielectric layer on the top surface of the doped semiconductor layer 202 and on the bottom surface of the recess 502. The remaining portions of the dielectric layer 504 correspond to the dielectric isolation layers 214 of the deep trench structure 210 on the sidewalls of the recess 502. In some implementations, an etch tool may be used to perform an anisotropic etch operation in which vertical etching is used to remove the portions of the dielectric layer on the top surface of the doped semiconductor layer 202 and on the bottom surface of the recess 302.

As further shown in FIG. 5D, the dielectric isolation layers 214 may be formed to a lateral length (or width) of a dielectric isolation layer 214 in the x-direction (dimension D6) that may be included in a range of approximately 500 nanometers to approximately 1500 nanometers. A remaining lateral width of the recess 502 after formation of the dielectric isolation layer 214 (dimension D5) may be included in a range of approximately 1 micron to approximately 2 microns. However, other values for these ranges are within the scope of the present disclosure.

As shown in FIG. 5E, a doped implant region 402 may be formed at the bottom of the recess 502. In some implementations, an ion implant tool is used to implant ions in the doped semiconductor layer 202 at the bottom of the recess 502. The ions may correspond to dopants that are implanted into the doped semiconductor layer 202 at the bottom of the recess 502.

As shown in FIG. 5F, the vertical source/drain region 212 of the integrated circuit device 108 may be formed in the remaining area in the recess 502 such that the vertical source/drain region 212 lands on the doped implant region 402 at the bottom of the recess 502. In some implementations, a deposition tool is used to deposit the polysilicon material of the vertical source/drain region 212 by CVD, ALD, and/or another suitable deposition technique, which may enable the vertical source/drain region 212 to be formed by lower cost and/or lower complexity processes compared to epitaxial growth that might otherwise be used if the vertical source/drain region 212 were formed of silicon (Si).

Alternatively, the doped implant region 402 may also be formed of doped polysilicon and may be formed in the same deposition operation as the vertical source/drain region 212.

As shown in FIG. 5G, the source/drain region 208, the gate structure 216, the gate dielectric layer 220, the sidewall spacers 222, the body implant region 224, the dielectric layer 110, and the contact structures 112a-112c may be formed in a similar manner as described in connection with FIGS. 3H-3K.

As indicated above, FIGS. 5A-5G are provided as an example. Other examples may differ from what is described with regard to FIGS. 5A-5G.

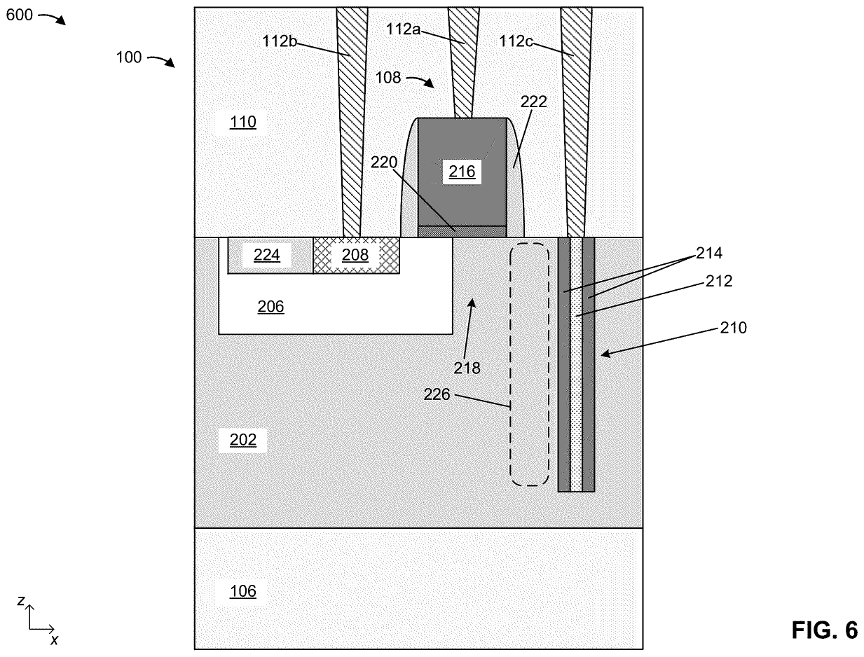

FIG. 6 is a diagram of an example implementation 600 of an integrated circuit device 108 described herein. In the example implementation 600, the integrated circuit device 108 includes a VDMOS transistor. As shown in FIG. 6, the example implementation 600 of the integrated circuit device 108 includes a similar combination and arrangement of layers and/or structures as the example implementation 200 of the integrated circuit device 108 in FIGS. 2A and 2B. However, in the example implementation 600 of the integrated circuit device 108, the doped buried semiconductor layer 204 is omitted. Omitting the doped buried semiconductor layer 204 (and omitting a doped implant region 402) enables the integrated circuit device 108 to be formed using fewer processing operations, thereby reducing the complexity, time, and/or cost of manufacturing the integrated circuit device 108.

As indicated above, FIG. 6 is provided as an example. Other examples may differ from what is described with regard to FIG. 6.

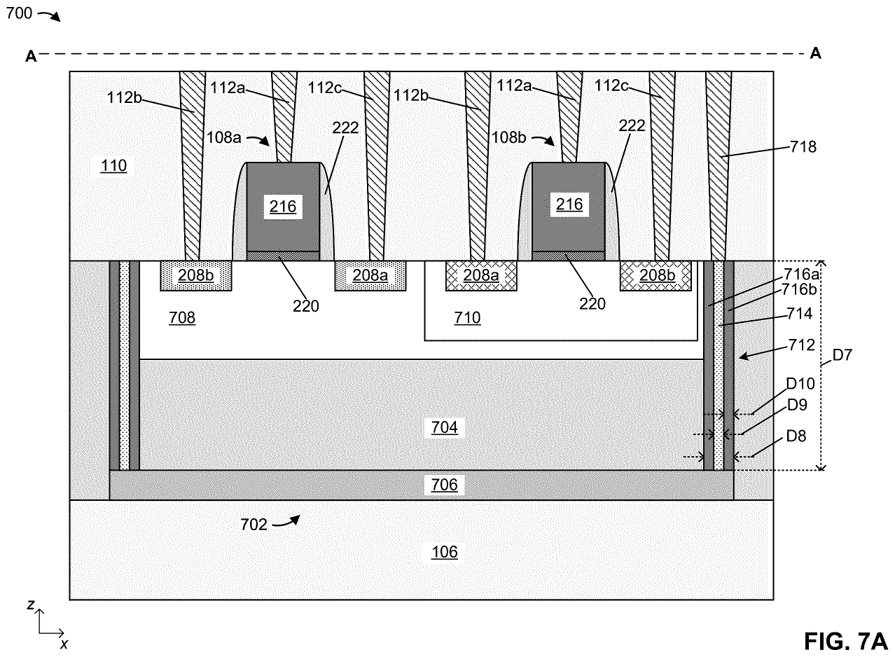

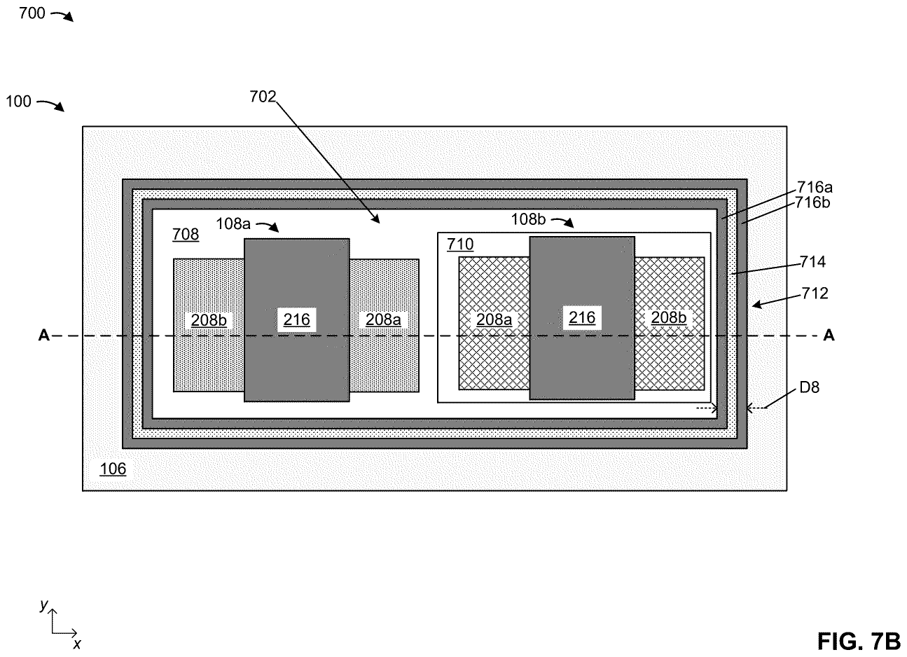

FIGS. 7A and 7B are diagrams of an example implementation 700 of an isolated device region 702 of the semiconductor device 100 described herein. The isolated device region 702 includes an electrically isolated region of integrated circuit devices 108 in the semiconductor device 100. In some implementations, a plurality of types of integrated circuit devices 108 may be included in the isolated device region 702, including a first type transistor structure such as an n-type transistor structure (e.g., an integrated circuit device 108a) and a second type transistor structure such as a p-type transistor structure (e.g., an integrated circuit device 108b). In some implementations, additional integrated circuit devices 108 may be included in the isolated device region 702.

FIG. 7A illustrates a cross-section view of the isolated device region 702 along a line A-A, and FIG. 7B illustrates a top view of the isolated device region 702. As shown in FIG. 7A, a doped semiconductor layer 704 (similar to the doped semiconductor layer 202) may be included above the bottom semiconductor layer 106 of the semiconductor device 100. A doped buried semiconductor layer 706 (similar to the doped buried semiconductor layer 204) may be included between the doped semiconductor layer 704 and the bottom semiconductor layer 106.

As further shown in FIG. 7A, a first type doped well region 708 may be included in the doped semiconductor layer 704, and a second type doped well region 710 may be included in the first type doped well region 708. In some implementations, the first type doped well region 708 includes a p-type well region, which may include a portion of the doped semiconductor layer 704 that is doped with one or more p-type dopants. In some implementations, the second type doped well region 710 includes an n-type well region, which may include a portion of the doped semiconductor layer 704 that is doped with one or more n-type dopants. The integrated circuit device 108a may be included in and/or on the first type doped well region 708, and may include an n-type transistor structure. The integrated circuit device 108b may be included in and/or on the second type doped will region 710, and may include a p-type transistor structure.

As further shown in FIG. 7A, a DTI structure 712 may be included in the doped semiconductor layer 704 and may laterally surround the integrated circuit devices 108a and 108b. The DTI structure 712 may also laterally surround the first type doped well region 708 and the second type doped well region 710. The DTI structure 712 may be similar to the deep trench structure 210, and may be an elongated structure that is elongated in the z-direction and may extend vertically in the doped semiconductor layer 704. Moreover, the DTI structure 712 may include a doped polysilicon insert 714 (similar to the vertical source/drain region 212) that is elongated in the z-direction and may extend vertically in the doped semiconductor layer 704, and dielectric layers 716a and 716b (similar to the dielectric isolation layers 214). The dielectric layers 716a and 716b (e.g., dielectric isolation layer segments) may be located on opposing sidewalls of the doped polysilicon insert 714. The DTI structure 712 may be included on the doped buried semiconductor layer 706.

As further shown in FIG. 7A, a contact structure 718 may be included in the dielectric layer 110 and may be included on the doped polysilicon insert 714. The contact structure 718 may be used to electrically connect the doped polysilicon insert 714 to a voltage bias (e.g., a 0-voltage bias, a forward bias, a reverse bias) or may be used to electrically connect the doped polysilicon insert 714 to electrical ground.

As further shown in FIG. 7A, the DTI structure 712 may have one or more dimensions. An example dimension D7 may correspond to a vertical (z-direction) height of the DTI structure 712, which also corresponds to the vertical (z-direction) height of the vertical doped polysilicon insert 714. In some implementations, the vertical height of the DTI structure 712 (and the vertical height of the doped polysilicon insert 714) may be included in a range of approximately 5 microns to approximately 30 microns. If the vertical height of the DTI structure 712 (and the vertical height of the doped polysilicon insert 714) is less than approximately 5 microns, the DTI structure 712 may be unable to be connected to the underlying doped buried semiconductor layer 706, which may result in increased current leakage in the isolated device region 702. If the vertical height of the DTI structure 712 (and the vertical height of the doped polysilicon insert 714) is greater than approximately 30 microns, the DTI structure 712 may extend through the underlying doped buried semiconductor layer 706, which may result in the doped buried semiconductor layer 706 being unable to be electrically biased. However, other values and ranges other than approximately 5 microns to approximately 30 microns for the vertical height of the DTI structure 712 (and the vertical height of the doped polysilicon insert 714) are within the scope of the present disclosure.

Another example dimension D8 may correspond to a lateral length (or width) of the overall DTI structure 712 in the x-direction, another example dimension D9 may correspond to a lateral length (or width) of the doped polysilicon insert 714 in the x-direction, and another example dimension D10 may correspond to a lateral length (or width) of a dielectric layer 716 in the x-direction. In some implementations, the lateral length (or width) of the DTI structure 712 in the x-direction may be included in a range of approximately 2 microns to approximately 5 microns. However, other values and ranges other than approximately 2 microns to approximately 5 microns are within the scope of the present disclosure.

In some implementations, the lateral length (or width) of the doped polysilicon insert 714 in the x-direction may be included in a range of approximately 1 micron to approximately 2 microns. However, other values and ranges other than approximately 1 micron to approximately 2 microns are within the scope of the present disclosure.

In some implementations, the lateral length (or width) of a dielectric layer 716 in the x-direction may be included in a range of approximately 500 nanometers to approximately 1500 nanometers. However, other values and ranges other than approximately 500 nanometers to approximately 1500 nanometers are within the scope of the present disclosure.

In some implementations, an aspect ratio of the DTI structure 712 (e.g., a ratio of the vertical (z-direction) height of the doped polysilicon insert 714 to the lateral length (or width) of the DTI structure 712 in the x-direction) is included in a range of approximately 3:1 to approximately 20:1. However, other values and ranges other than approximately 3:1 to approximately 20:1 for the aspect ratio of the DTI structure 712 (and the vertical height of the DTI structure 712) are within the scope of the present disclosure.

As shown in FIG. 7B, the DTI structure 712 may laterally surround the integrated circuit devices 108a and 108b in the isolated device region 702, and may electrically isolate the integrated circuit devices 108a and 108b in the isolated device region 702 from other regions of the semiconductor device 100. The first type doped well region 708 and the second type doped well region 710 may also be contained within the isolated device region 702.

As further shown in FIG. 7B, the dielectric layers 716a and 716b each include closed-loop top view shapes, and the doped polysilicon layer 714 includes a closed-loop view shape. The doped polysilicon layer 714 may be included within a perimeter of an outer dielectric layer 716b, and an inner dielectric layer 716a may be included within a perimeter of the doped polysilicon layer 714. The dielectric layers 716a and 716b may be spaced apart from each other by the doped poly silicon layer 714.

As further shown in FIG. 7B, a lateral width (dimension D8) of the DTI structure 712 may be across the DTI structure 712 in the x-direction. In other words, the lateral width (dimension D8) of the DTI structure 712 may be across the short dimension of the doped polysilicon insert 714 and across the short dimensions of the dielectric layers 716a and 716b in the x-direction, as opposed to being along the long dimensions of the doped polysilicon insert 714 and the dielectric layers 716a and 716b in the x-direction. Thus, the lateral width (dimension D8) of the DTI structure 712 is approximately perpendicular to a length of a segment of the DTI structure 712 that extends in the y-direction.

As indicated above, FIGS. 7A and 7B are provided as an example. Other examples may differ from what is described with regard to FIGS. 7A and 7B.

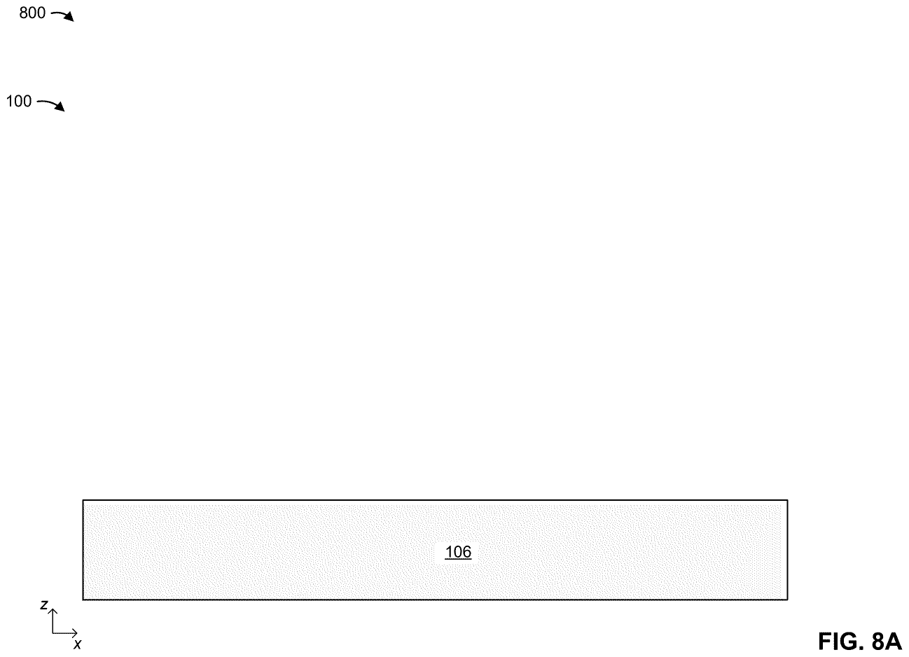

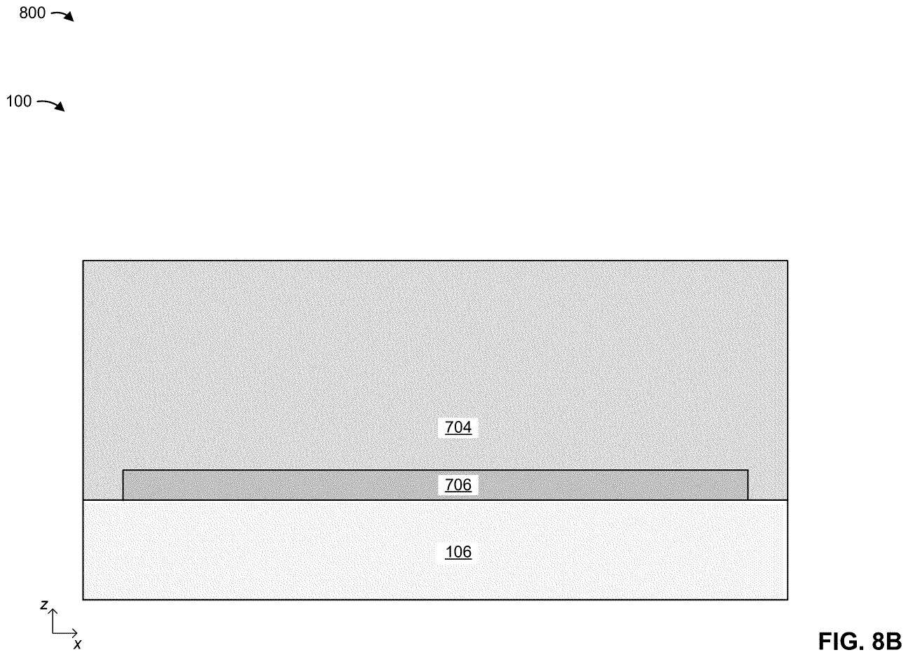

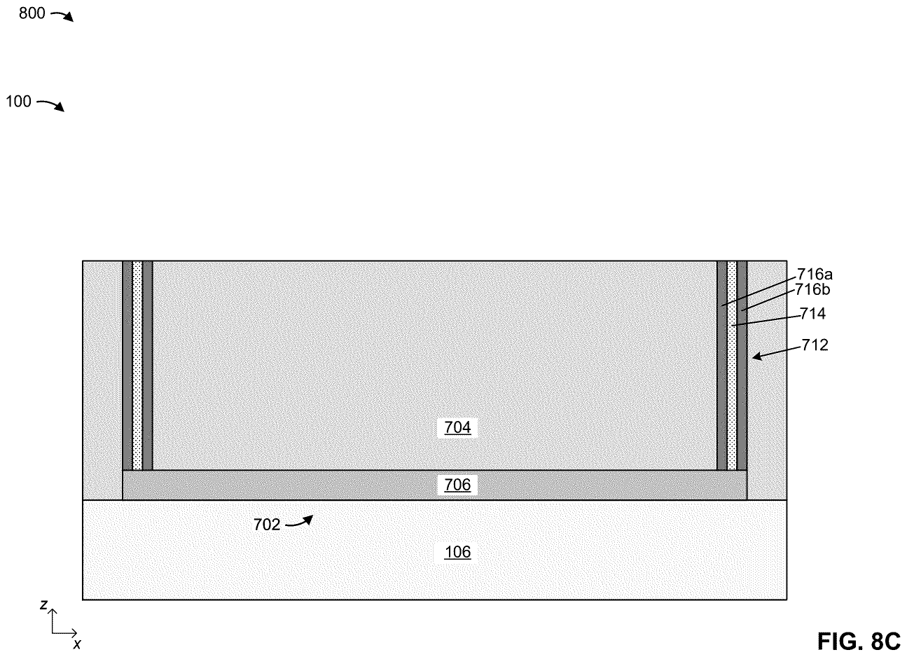

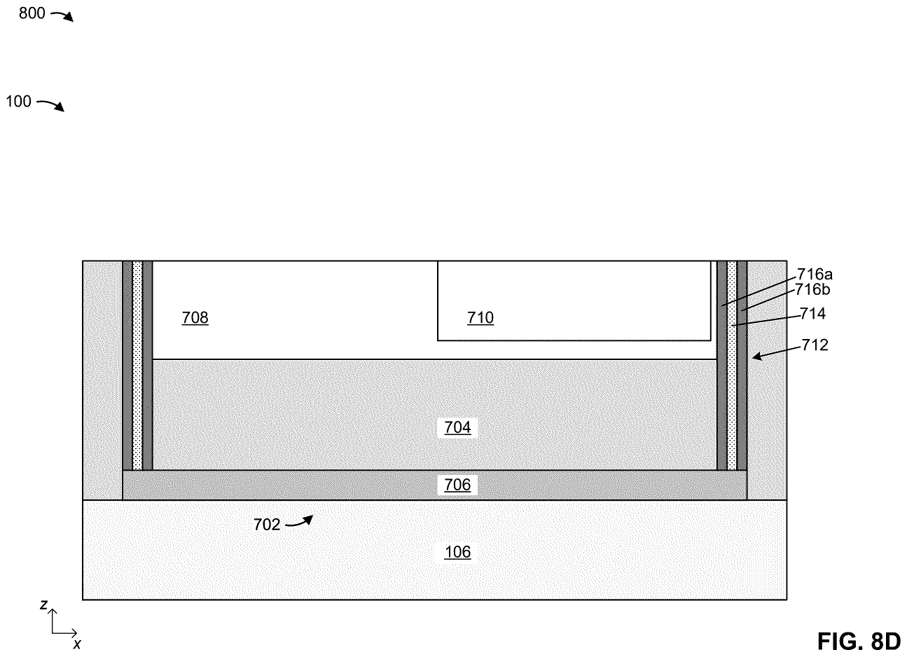

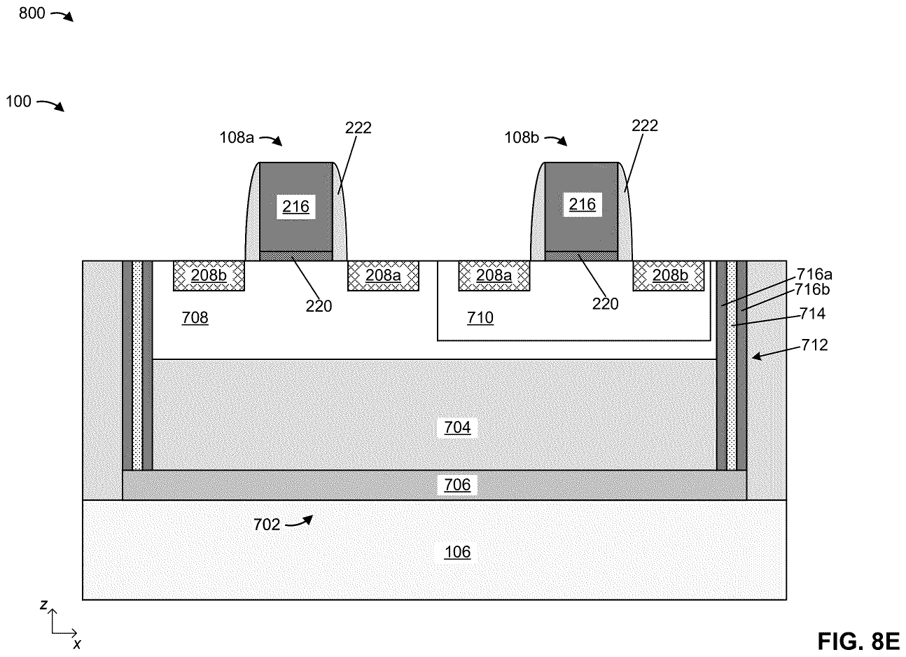

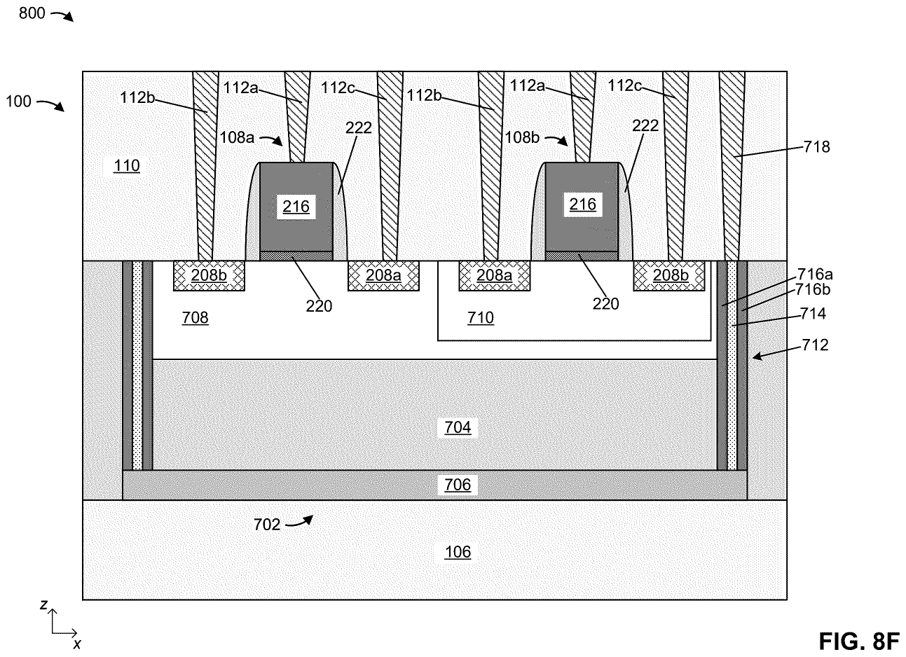

FIGS. 8A-8F are diagrams of an example implementation 800 of forming an isolated device region 702 in the semiconductor device 100 described herein. In some implementations, one or more of the operations described in connection with FIGS. 8A-8F may be performed using one or more semiconductor processing tools, such as a deposition tool, an exposure tool, a developer tool, an etch tool, an ion implantation tool, a planarization tool, and/or another suitable semiconductor processing tool.

Turning to FIG. 8A, one or more of the operations in the example implementation 800 may be performed in connection with the bottom semiconductor layer 106 of the semiconductor device 100. The bottom semiconductor layer 106 may be provided in the form of a semiconductor wafer or another type of substrate, or a portion thereof.

As shown in FIG. 8B, the doped semiconductor layer 704 and the doped buried semiconductor layer 706 may be formed above the bottom semiconductor layer 106 of the semiconductor device 100. The doped semiconductor layer 704 and the doped buried semiconductor layer 706 may be formed in a similar manner as the doped semiconductor layer 202 and the doped buried semiconductor layer 204 described in connection with FIGS. 3B and 3C.

As shown in FIG. 8C, the DTI structure 712 may be formed in the doped semiconductor layer 704 to form the isolated device region 702. The DTI structure 712 may be formed such that the DTI structure 712 is formed on the doped buried semiconductor layer 706. The DTI structure 712 may be formed in a similar manner as described in connection with FIGS. 3D-3G for the deep trench structure 210. For example, the dielectric layers 716 may be formed on the sidewalls of a recess in the doped semiconductor layer 704 (e.g., in a similar manner as described in connection with FIGS. 3D-3F for the dielectric isolation layers 214). As another example, the doped polysilicon insert 714 may be formed in the recess (e.g., in a similar manner as described in connection with FIG. 3G for the vertical sourced/drain region 212).

As shown in FIG. 8D, portions of the doped semiconductor layer 704 within the perimeter of the DTI structure 712 may be doped to form the first type doped well region 708 and the second type doped well region 710. An ion implantation may be used to deposit first type ions (e.g., n-type ions) in the doped semiconductor layer 704 to form the first type doped well region 708, and may be used to deposit second type ions (e.g., p-type ions) in the doped semiconductor layer 704 to form the second type doped well region 710.

As shown in FIG. 8E, the integrated circuit device 108a may be formed in and/or on the first type doped well region 708 within the perimeter of the DTI structure 712 (e.g., within the isolated device region 702). The integrated circuit device 108b may be formed in and/or on the second type doped well region 710 within the perimeter of the DTI structure 712 (e.g., within the isolated device region 702).

As shown in FIG. 8F, the dielectric layer 110 may be formed on the integrated circuit devices 108a and 108b, and contact structures may be formed in the dielectric layer 110 for the integrated circuit devices 108a and 108b. As further shown in FIG. 8F, the contact structure 718 may be formed in the dielectric layer 110 such that the contact structure 718 lands on the doped polysilicon insert 714 of the DTI structure 712.

As indicated above, FIGS. 8A-8F are provided as an example. Other examples may differ from what is described with regard to FIGS. 8A-8F.

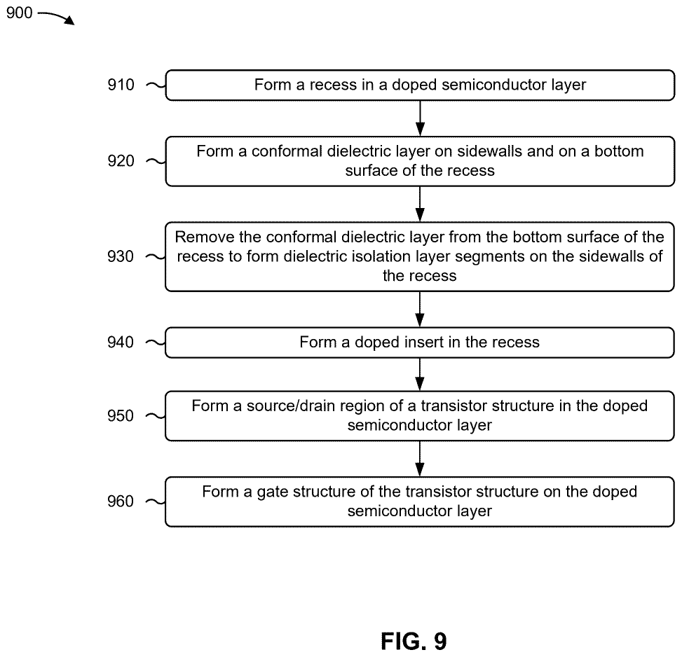

FIG. 9 is a flowchart of an example process 900 associated with forming a semiconductor device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include forming a recess in a doped semiconductor layer (block 910). For example, one or more semiconductor processing tools may be used to form a recess (e.g., a recess 302, a recess 502) in a doped semiconductor layer (e.g., a doped semiconductor layer 202, a doped semiconductor layer 704), as described herein. In some implementations, an etch tool is used to etch the doped semiconductor layer of the semiconductor device to form the recess in the doped semiconductor layer.

As further shown in FIG. 9, process 900 may include forming a conformal dielectric layer on sidewalls and on a bottom surface of the recess (block 920). For example, one or more semiconductor processing tools may be used to form a conformal dielectric layer (e.g., a dielectric layer 304, a dielectric layer 504) on sidewalls and on a bottom surface of the recess, as described herein. In some implementations, a deposition tool is used to deposit the conformal dielectric layer on the sidewalls and on the bottom surface of the recess.

As further shown in FIG. 9, process 900 may include removing the conformal dielectric layer from the bottom surface of the recess to form dielectric isolation layer segments on the sidewalls of the recess (block 930). For example, one or more semiconductor processing tools may be used to remove the conformal dielectric layer from the bottom surface of the recess to form dielectric isolation layer segments (e.g., dielectric isolation layers 214, isolation layers 716a and 716b) on the sidewalls of the recess, as described herein. In some implementations, an etch tool is used to etch the conformal dielectric layer to remove a portion of the conformal dielectric layer from the bottom surface of the recess to form dielectric isolation layer segments on the sidewalls of the recess. In some implementations, a first dielectric isolation layer segment of the dielectric isolation layer segments is located on a first sidewall of the sidewalls, and a second dielectric isolation layer segment dielectric isolation layer segments is located on a second opposing sidewall of the sidewalls.

As further shown in FIG. 9, process 900 may include forming a doped insert in the recess (block 940). For example, one or more semiconductor processing tools may be used to form a doped insert (e.g., a vertical source/drain region 212, a doped polysilicon insert 714) in the recess, as described herein. In some implementations, a deposition tool is used to deposit material in an area in the recess between the dielectric isolation layer segments to form a doped insert. In some implementations, the dielectric isolation layer segments and the doped insert correspond to an elongated structure (e.g., a deep trench structure 210, a DTI structure 712) of the semiconductor device.

As further shown in FIG. 9, process 900 may include forming a source/drain region of the transistor structure in the doped semiconductor layer (block 950). For example, one or more

semiconductor processing tools may be used to form a source/drain region (e.g., a source/drain region 208, a source/drain region 208a, a source/drain region 208b) of a transistor structure (e.g., an integrated circuit device 108, an integrated circuit device 108a, an integrated circuit device 108b) in the doped semiconductor layer, as described herein. In some implementations, the source/drain region and the elongated structure are spaced apart by a portion of the doped semiconductor layer.

As further shown in FIG. 9, process 900 may include forming a gate structure of the transistor structure on the doped semiconductor layer (block 960). For example, one or more semiconductor processing tools may be used to form a gate structure (e.g., a gate structure 216) of the transistor structure on the doped semiconductor layer, as described herein. In some implementations, the gate structure is located laterally between the source/drain region and the elongated structure.

Process 900 may include additional implementations, such as any single implementation or any combination of implementations described below and/or in connection with one or more other processes described elsewhere herein.

In a first implementation, forming the recess includes forming the recess such that a ratio of a vertical height (e.g., a dimension D2) of the recess to a lateral width (e.g., dimension D4) of the recess is included in a range of approximately 3:1 to approximately 20:1.

In a second implementation, alone or in combination with the first implementation, process 900 includes forming a doped buried semiconductor layer (e.g., a doped buried semiconductor layer 204) prior to forming the recess.

In a third implementation, alone or in combination with one or more of the first and second implementations, forming the recess includes forming the recess such that the bottom surface of the recess corresponds to a top surface of the doped buried semiconductor layer.

In a fourth implementation, alone or in combination with one or more of the first through third implementations, process 900 includes doping the bottom surface of the recess to form a doped implant region (e.g., a doped implant region 402).

In a fifth implementation, alone or in combination with one or more of the first through fourth implementations, filling the area in the recess between the dielectric isolation layers with the first source/drain region includes forming the first source/drain region on the doped implant region.

In a sixth implementation, alone or in combination with one or more of the first through fifth implementations, doping the bottom surface of the recess to form the doped implant region includes doping the bottom surface of the recess to form the doped implant region after forming the dielectric isolation layers on the sidewalls of the recess.

In a seventh implementation, alone or in combination with one or more of the first through sixth implementations, a top of the doped insert is lower in the semiconductor device than a bottom of the gate structure.

In an eighth implementation, alone or in combination with one or more of the seventh through fifth implementations, the process 900 includes doping a portion of the doped semiconductor layer forming a doped buried semiconductor layer prior to forming the recess.

In a ninth implementation, alone or in combination with one or more of the first through eighth implementations, forming the recess includes etching the doped semiconductor layer to form the recess such that the bottom surface of the recess corresponds to a top surface of the doped buried semiconductor layer.

In a tenth implementation, alone or in combination with one or more of the first through ninth implementations, the process 900 includes doping the bottom surface of the recess to form a doped implant region prior to forming the doped insert.

In an eleventh implementation, alone or in combination with one or more of the first through tenth implementations, filling the area in the recess between the dielectric isolation layers with the first source/drain region includes forming the first source/drain region on the doped implant region.

In a twelfth implementation, alone or in combination with one or more of the first through eleventh implementations, doping the bottom surface of the recess to form the doped implant region includes doping the bottom surface of the recess to form the doped implant region after forming the dielectric isolation layer segments on the sidewalls of the recess.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a deep trench structure may be formed to include a doped polysilicon core and dielectric isolation layers on the sidewalls of the doped polysilicon core. The deep trench structure may be included in a high-voltage transistor as a vertical drain region that extends into a semiconductor layer of a semiconductor device. The vertical drain region may be electrically isolated from the semiconductor layer by the dielectric isolation layers that extend along the sidewalls of the vertical drain region. The electrical isolation provided by the dielectric isolation layers enables the diffusion region of the high-voltage transistor to extend vertically in the semiconductor layer as opposed to horizontally, which enables the vertical drain region to be positioned closer to the gate structure of the high-voltage transistor. Additionally and/or alternatively, the deep trench structure may be provided as a DTI structure that laterally surrounds transistors in a semiconductor device. The use of the DTI structure for electrical isolation enables less complex manufacturing processes to be used to connect the DTI structure to an underlying doped buried layer than if other electrical isolation techniques were used (such as those formed by multi-step epitaxy). Moreover, this enables the doped buried layer to be positioned deeper in the semiconductor layer, which provides for a greater area in the semiconductor layer for transistors. In addition, the DTI structure may be more resistant to electrical effects such as parasitic capacitance, parasitic P-N junction formation, parasitic BJT formation, and/or current leakage, among other examples. Further, the DTI structure may be formed to have a high aspect ratio (e.g., a ratio of a depth to a width), which enables the DTI structure to occupy a smaller lateral footprint than other types of electrical isolation. This provides for a greater area in the semiconductor layer for transistors.

As described in greater detail above, some implementations described herein provide a semiconductor device. The semiconductor device includes a source/drain region in a doped semiconductor region. The semiconductor device includes an elongated structure having a doped insert. The elongated structure is located in the doped semiconductor region. A height of the elongated structure is greater than a width of the elongated structure. The semiconductor device includes a first dielectric layer along sidewalls of the doped insert of the elongated structure. The first dielectric layer extends along the height of the elongated structure. The width of the elongated structure is across the doped insert and the first dielectric layer. The semiconductor device includes a gate structure over the doped semiconductor region and laterally between the source/drain region and the elongated structure. The semiconductor device includes a second dielectric layer between the doped semiconductor region and the gate structure. The second dielectric layer is laterally between the source/drain region and the elongated structure. The semiconductor device includes a first contact structure above and coupled to the source/drain region. The semiconductor device includes a second contact structure above and coupled to the doped insert of the elongated structure. The first contact structure and the second contact structure are located adjacent to opposing sides of the gate structure.

As described in greater detail above, some implementations described herein provide a method. The method includes etching a doped semiconductor layer of a semiconductor device to form a recess in the doped semiconductor layer. The method includes depositing a conformal dielectric layer on sidewalls and on a bottom surface of the recess. The method includes etching the conformal dielectric layer to remove a portion of the conformal dielectric layer from the bottom surface of the recess to form dielectric isolation layer segments on the sidewalls of the recess. A first dielectric isolation layer segment of the dielectric isolation layer segments is located on a first sidewall of the sidewalls, and a second dielectric isolation layer segment dielectric isolation layer segments is located on a second opposing sidewall of the sidewalls. The method includes depositing material in an area in the recess between the dielectric isolation layer segments to form a doped insert. The dielectric isolation layer segments and the doped insert correspond to an elongated structure of the semiconductor device. The method includes forming a source/drain region of a transistor structure in the doped semiconductor layer. The source/drain region and the elongated structure are spaced apart by a portion of the doped semiconductor layer. The method includes forming a gate structure of the transistor structure on the doped semiconductor layer. The gate structure is located laterally between the source/drain region and the of a semiconductor device.

As described in greater detail above, some implementations described herein provide a semiconductor device. The semiconductor device includes a first doped semiconductor region above a bottom semiconductor layer of the semiconductor device. The semiconductor device includes a second doped semiconductor region in the first doped semiconductor region, where the first doped semiconductor region includes a first dopant type, and where the second doped semiconductor region includes a second dopant type that is different from the first dopant type. The semiconductor device includes a first type transistor structure in the first doped semiconductor region. The semiconductor device includes a second type transistor structure in the second doped semiconductor region. The semiconductor device includes a DTI structure laterally surrounding the first type transistor structure and the second type transistor structure, where the DTI structure includes a doped polysilicon insert.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a source/drain region in a doped semiconductor region;
an elongated structure having a doped insert,
wherein the elongated structure is located in the doped semiconductor region, and
wherein a height of the elongated structure is greater than a width of the elongated structure;
a first dielectric layer along sidewalls of the doped insert of the elongated structure,
wherein the first dielectric layer extends along the height of the elongated structure, and
wherein the width of the elongated structure is across the doped insert and the first dielectric layer;
a gate structure over the doped semiconductor region and laterally between the source/drain region and the elongated structure;
a second dielectric layer between the doped semiconductor region and the gate structure,
wherein the second dielectric layer is laterally between the source/drain region and the elongated structure;
a first contact structure above and coupled to the source/drain region; and
a second contact structure above and coupled to the doped insert of the elongated structure,
wherein the first contact structure and the second contact structure are located adjacent to opposing sides of the gate structure.

2. The semiconductor device of claim 1, wherein a lateral distance between the source/drain region and the elongated structure is less than the height of the elongated structure.

3. The semiconductor device of claim 1, further comprising:
a doped buried semiconductor layer under the elongated structure and extending under the gate structure and the source/drain region.

4. The semiconductor device of claim 3, wherein the doped buried semiconductor layer and the doped insert are doped with a same dopant type.

5. The semiconductor device of claim 1, further comprising:
another doped semiconductor region under the elongated structure,
wherein the doped semiconductor region comprises a first dopant type,
wherein the other doped semiconductor region comprises a second dopant type, and
wherein the first dopant type and the second dopant type are different dopant types.

6. The semiconductor device of claim 5, wherein a bottom of the doped insert is in contact with the other doped semiconductor region.

7. The semiconductor device of claim 6, wherein the doped insert corresponds to another source/drain region.

8. A method, comprising:
etching a doped semiconductor layer of a semiconductor device to form a recess in the doped semiconductor layer;
depositing a conformal dielectric layer on sidewalls and on a bottom surface of the recess;
etching the conformal dielectric layer to remove a portion of the conformal dielectric layer from the bottom surface of the recess to form dielectric isolation layer segments on the sidewalls of the recess,
wherein a first dielectric isolation layer segment of the dielectric isolation layer segments is located on a first sidewall of the sidewalls, and a second dielectric isolation layer segment dielectric isolation layer segments is located on a second opposing sidewall of the sidewalls;
depositing material in an area in the recess between the dielectric isolation layer segments to form a doped insert,
wherein the dielectric isolation layer segments and the doped insert correspond to an elongated structure of the semiconductor device;
forming a source/drain region of a transistor structure in the doped semiconductor layer,
wherein the source/drain region and the elongated structure are spaced apart by a portion of the doped semiconductor layer; and
forming a gate structure of the transistor structure on the doped semiconductor layer,
wherein the gate structure is located laterally between the source/drain region and the elongated structure.

9. The method of claim 8, wherein a top of the doped insert is lower in the semiconductor device than a bottom of the gate structure.

10. The method of claim 8, further comprising:
doping a portion of the doped semiconductor layer forming a doped buried semiconductor layer prior to forming the recess.

11. The method of claim 10, wherein forming the recess comprises:
etching the doped semiconductor layer to form the recess such that the bottom surface of the recess corresponds to a top surface of the doped buried semiconductor layer.

12. The method of claim 8, further comprising:
doping the bottom surface of the recess to form a doped implant region prior to forming the doped insert.

13. The method of claim 12, wherein depositing material in the area in the recess between the dielectric isolation layer segments to form the doped insert comprises:
depositing material in the area in the recess between the dielectric isolation layer segments to form the doped insert on the doped implant region.

14. The method of claim 12, wherein doping the bottom surface of the recess to form the doped implant region comprises:
doping the bottom surface of the recess to form the doped implant region after forming the dielectric isolation layer segments on the sidewalls of the recess.

15. A semiconductor device, comprising:
a first doped semiconductor region above a bottom semiconductor layer of the semiconductor device;
a second doped semiconductor region in the first doped semiconductor region,
wherein the first doped semiconductor region comprises a first dopant type, and
wherein the second doped semiconductor region comprises a second dopant type that is different from the first dopant type;
a first type transistor structure in the first doped semiconductor region;
a second type transistor structure in the second doped semiconductor region; and
a deep trench isolation (DTI) structure laterally surrounding the first type transistor structure and the second type transistor structure,
wherein the DTI structure comprises a doped polysilicon insert.

16. The semiconductor device of claim 15, wherein the DTI structure further comprises:
a plurality of dielectric layers on sidewalls of the doped polysilicon insert.

17. The semiconductor device of claim 15, wherein the doped polysilicon insert comprises the second dopant type.

18. The semiconductor device of claim 15, further comprising:
a contact structure on the DTI structure,
wherein the contact structure is electrically connected to the doped polysilicon insert.

19. The semiconductor device of claim 15, wherein the first dopant type comprises a p-type dopant;
wherein the second dopant type comprises an n-type dopant; and
wherein the doped polysilicon insert comprises the n-type dopant.

20. The semiconductor device of claim 15, further comprising:
an n-type buried semiconductor layer under the first type transistor structure, under the second type transistor structure, and under the DTI structure.
